(19) United States
(12) Patent Application Publication
(10) Pub. No.: US 2023/0411250 A1
(43) Pub. Date: Dec. 21, 2023

(54) POWER CONVERTER AND POWER CONVERTER MANUFACTURING METHOD

(71) Applicant: FUJI ELECTRIC CO., LTD., Kawasaki-shi (JP)

(72) Inventors: Norihiro DAICHO, Matsumoto-city (JP); Taichi ITOH, Matsumoto-city (JP)

(73) Assignee: FUJI ELECTRIC CO., LTD., Kawasaki-shi (JP)

(21) Appl. No.: 18/305,539

(22) Filed: Apr. 24, 2023

(30) Foreign Application Priority Data
Jun. 16, 2022 (JP) 2022-097270

(51) Int. Cl. H01L 23/495; H01L 23/043

(52) U.S. Cl. CPC H01L 23/4952; H01L 23/043; H01L 23/49531; H01L 23/49551

(57) ABSTRACT

A power converter includes a case including an outlet with an outlet opening in a principal surface thereof, and a wiring member having, as an external connection portion, a portion that extends out from the outlet opening and is bent at the outlet opening toward the principal surface. The external connection portion of the wiring member has a first surface facing the principal surface and includes a spacer provided on the first surface at a position adjacent to the outlet opening. The spacer is sandwiched between the first surface of the drawn-out portion and the principal surface of the case.

### CROSS-REFERENCE TO RELATED APPLICATION

This application is based upon and claims the benefit of priority of the prior Japanese Patent Application No. 2022-097270, filed on Jun. 16, 2022, the entire contents of which are incorporated herein by reference.

### BACKGROUND OF THE INVENTION

### 1. Field of the Invention

The embodiments discussed herein relate to a power converter and a power converter manufacturing method.

### 2. Background of the Related Art

A power converter includes semiconductor elements such as insulated gate bipolar transistors (IGBTs) or power metal oxide semiconductor field effect transistors (MOSFETs). A power converter includes a heat radiation base plate, a plurality of insulated circuit boards which are bonded to the heat radiation base plate and over which semiconductor elements are located, and lead frames which are wiring members and which are electrically connected to the plurality of insulated circuit boards. Such a power converter includes a case. The case is fixed to the heat radiation base plate and covers the semiconductor elements and the plurality of insulated circuit boards. Furthermore, the lead frames are drawn out from an outlet of the case and are bent with respect to the case (see, for example, the literature (1) to (10) below). A technique for preventing floating of a lead frame caused by bending the lead frame in this way is proposed (see, for example, the literature (1), (2), and (6) to (10) below). Furthermore, a technique for preventing the appearance of a crack in a lead frame caused by bending the lead frame is proposed (see, for example, the literature (10) below). In addition, a technique for improving the heat resistance property of a case at the time of soldering a bent lead frame is proposed (see, for example, the literature (11) below).

Furthermore, fixing a case in a power converter is performed in the following way. First, a case is fixed so that a lead frame drawn out from an outlet of the case will extend vertically upward from the front surface of the case. The lead frame extending vertically upward from the outlet of the case is bent with respect to the principal surface of the case. By doing so, the case is fixed.
(1) Japanese Laid-open Patent Publication No. H11-126842
(2) Japanese Laid-open Patent Publication No. H09-045831
(3) Japanese Laid-open Patent Publication No. 2011-018933
(4) Japanese Laid-open Patent Publication No. 2015-053301
(5) Japanese Laid-open Patent Publication No. 2019-102758
(6) Japanese Laid-open Patent Publication No. H07-099276
(7) Japanese Laid-open Patent Publication No. 2021-150606
(8) Japanese Laid-open Patent Publication No. 2015-173138
(9) Japanese Laid-open Patent Publication No. H10-256411
(10) Japanese Laid-open Patent Publication No. H04-072748
(11) Japanese Laid-open Patent Publication No. 2016-157826

A lead frame which is a wiring member is made of metal. Accordingly, after the case is fixed, the lead frame bent with respect to the case attempts to return to the original position in order to restore a state in which it is not yet bent (springback). That is to say, the lead frame is inclined with respect to the principal surface of the case with the outlet side as a starting point and there is a space between the lead frame and the principal surface of the case. For example, if a printed-circuit board is fastened to the inclined lead frame with a screw, then the printed-circuit board made of resin strikes against the inclined lead frame and deforms. As a result, the printed-circuit board may be damaged. This deteriorates the reliability of the power converter.

### SUMMARY OF THE INVENTION

According to an aspect, there is provided a power converter, including: a case having principal surface, and including an outlet with an outlet opening at the principal surface; and a wiring member having, as a drawn-out portion, a portion that extends out from the outlet opening, and is bent at the outlet opening toward the principal surface, wherein the drawn-out portion of the wiring member has a first surface facing the principal surface and includes a spacer provided on the first surface at a position adjacent to the outlet opening, the spacer being sandwiched between the first surface of the drawn-out portion and the principal surface of the case.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a power converter according to a first embodiment;

FIG. 2 is a side view of the power converter according to the first embodiment;

FIG. 3 is a plan view of the inside of the power converter according to the first embodiment;

FIG. 4 is a plan view of a semiconductor unit included in the power converter according to the first embodiment;

FIG. 5 is a plan view of a wiring member included in the power converter according to the first embodiment;

FIG. 6 is a sectional view of the wiring member included in the power converter according to the first embodiment;

FIG. 7 is a flow chart illustrative of a method for manufacturing the power converter according to the first embodiment;

FIG. 8 illustrates a wiring member bonding process included in the method for manufacturing the power converter according to the first embodiment;

FIG. 9 illustrates a fixing process (under fixing) included in the method for manufacturing the power converter according to the first embodiment;

FIG. 10 illustrates the fixing process (after fixing) included in the method for manufacturing the power converter according to the first embodiment;

FIG. 11 illustrates a bending process included in the method for manufacturing the power converter according to the first embodiment (part 1);

FIG. 12 illustrates a bending process included in the method for manufacturing the power converter according to the first embodiment (part 2);

FIG. 13 illustrates a bending process included in a method for manufacturing a power converter taken as a reference example (part 1);

FIG. 14 illustrates a bending process included in a method for manufacturing a power converter taken as a reference example (part 2);

FIG. 15 illustrates press working of a wiring member included in the method for manufacturing the power converter according to the first embodiment (modification 1-1);

FIGS. 16A and 16B illustrate the wiring member included in the power converter according to the first embodiment (modification 1-1);

FIGS. 17A and 17B illustrate a wiring member included in the power converter according to the first embodiment (modification 1-2);

FIGS. 18A and 18B illustrate pressing of a wiring member included in the method for manufacturing the power converter according to the first embodiment (modification 1-3);

FIGS. 19A and 19B illustrate a wiring member included in the power converter according to the first embodiment (modification 1-3);

FIG. 20 illustrates a fixing process (after fixing) included in the method for manufacturing the power converter according to the first embodiment (modification 1-4);

FIG. 21 illustrates a bending process included in the method for manufacturing the power converter according to the first embodiment (modification 1-4);

FIG. 22 illustrates a fixing process (after fixing) included in a method for manufacturing a power converter according to a second embodiment;

FIG. 23 illustrates a bending process included in the method for manufacturing the power converter according to the second embodiment;

FIG. 24 illustrates a fixing process (after fixing) included in a method for manufacturing the power converter according to the second embodiment (modification 2-1);

FIG. 25 illustrates a bending process included in the method for manufacturing the power converter according to the second embodiment (modification 2-1);

FIG. 26 is a flow chart illustrative of a method for manufacturing a power converter according to a third embodiment;

FIG. 27 illustrates a fixing process (after fixing) included in the method for manufacturing the power converter according to the third embodiment;

FIG. 28 illustrates a spacer locating process included in the method for manufacturing the power converter according to the third embodiment;

FIG. 29 illustrates a bending process included in the method for manufacturing the power converter according to the third embodiment (part 1);

FIG. 30 illustrates a bending process included in the method for manufacturing the power converter according to the third embodiment (part 2); and

FIG. 31 illustrates a spacer removal process included in the method for manufacturing the power converter according to the third embodiment.

### DETAILED DESCRIPTION OF THE INVENTION

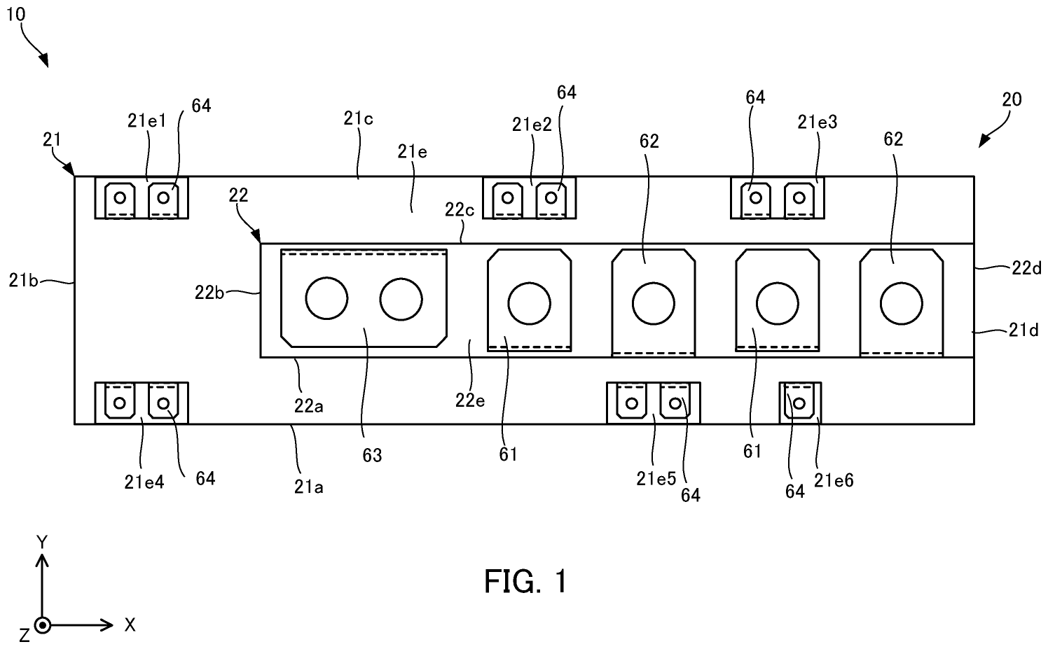

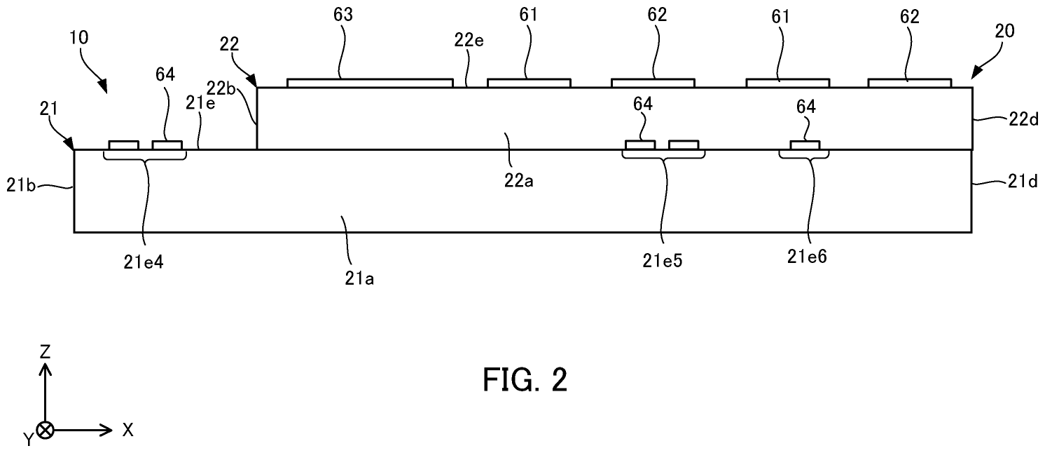

Embodiments will now be described with reference to the accompanying drawings. In the following description, a “front surface” or an “upper surface” indicates an X-Y plane which faces the upper side (+Z direction) in a power converter 10 of FIG. 1 and FIG. 2. Similarly, an “upside” indicates the upward direction (+Z direction) in the power converter 10 of FIG. 1 and FIG. 2. A “back surface” or a “lower surface” indicates the X-Y plane which faces the lower side (−Z direction) in the power converter 10 of FIG. 1 and FIG. 2. Similarly, a “downside” indicates the downward direction (−Z direction) in the power converter 10 of FIG. 1 and FIG. 2. These terms mean the same directions as needed in the other drawings. The “front surface,” the “upper surface,” the “upside,” the “back surface,” the “lower surface,” the “downside,” and a “side” are simply used as expedient representation for specifying relative positional relationships and do not limit the technical idea of the present disclosure. For example, the “upside” or the “downside” does not always mean the vertical direction relative to the ground. That is to say, a direction indicated by the “upside” or the “downside” is not limited to the gravity direction. Furthermore, in the following description, a “main ingredient” indicates an ingredient contained at a rate of 80 volume percent (vol %) or more. In addition, “approximately equal” means that two objects are in the range of ±10%. Moreover, “perpendicular” or “parallel” means that an angle which one object forms with the other object is in the range of 90°±10° or 180°±10°.

### First Embodiment

The power converter 10 according to a first embodiment will be described with reference to FIG. 1 and FIG. 2. FIG. 1 is a plan view of the power converter according to the first embodiment. FIG. 2 is a side view of the power converter according to the first embodiment. FIG. 1 and FIG. 2 illustrate the appearance of the power converter 10. FIG. 2 is a side view obtained when the power converter 10 of FIG. 1 is viewed in the +Y direction (from the underside to the upside in FIG. 1).

The power converter 10 includes a case 20. The case 20 is fixed to a heat radiation base plate which will be described later and to which semiconductor units are bonded. The case 20 houses the semiconductor units in a way described later. The case 20 includes a lower housing portion 21 and an upper housing portion 22.

The lower housing portion 21 has a rectangular parallelepiped shape. The lower housing portion 21 is surrounded in plan view on all sides by a long side wall 21a, a short side wall 21b, a long side wall 21c, and a short side wall 21d. Furthermore, the lower housing portion 21 includes a lower front surface (first principal surface) 21e and a lower back surface (second principal surface) opposite to each other, and the lower housing portion 21 has the lower front surface 21e in an opening surrounded by the long side wall 21a, the short side wall 21b, the long side wall 21c, and the short side wall 21d.

The lower front surface 21e includes control terminal areas 21e1 through 21e6. The control terminal area 21e1 is located on an edge portion of the long side wall 21c near the short side wall 21b of the lower front surface 21e. The control terminal area 21e2 is located on an edge portion of the long side wall 21c of the lower front surface 21e and on an approximately central portion of the long side wall 21c. The control terminal area 21e3 is located on an edge portion of the long side wall 21c of the lower front surface 21e between the control terminal area 21e2 and the short side wall 21d. The control terminal area 21e4 is located on an edge portion of the long side wall 21a opposite the control terminal area 21e1 near the short side wall 21b of the lower front surface 21e. The control terminal area 21e5 is located on an edge portion of the long side wall 21a of the lower front surface 21e and is located in side view between the control terminal areas 21e2 and 21e3. The control terminal area 21e6 is located on an edge portion of the long side wall 21a of the lower front surface 21e and is located in side view opposite the control terminal area 21e3.

In addition, as illustrated in FIG. 2, for example, the control terminal areas 21e4 through 21e6 are located on the lower front surface 21e. The control terminal areas 21e1 through 21e3 are also located on the lower front surface 21e (not illustrated). Control wiring members 64 are bent and are exposed from the control terminal areas 21e1 through 21e6. The control wiring members 64 are located on the control terminal areas 21e1 through 21e6. Moreover, nuts are located on the control terminal areas 21e1 through 21e6 so as to be opposed to the wiring members 64. The details of the wiring members 64 will be described later.

The upper housing portion 22 also has a rectangular parallelepiped shape. The upper housing portion 22 is surrounded in plan view on all sides by a long side wall 22a, a short side wall 22b, a long side wall 22c, and a short side wall 22d. Furthermore, the upper housing portion 22 includes an upper front surface 22e in an opening surrounded by the long side wall 22a, the short side wall 22b, the long side wall 22c, and the short side wall 22d. The upper housing portion 22 is formed on a central portion in the Y direction of the lower front surface 21e of the lower housing portion 21 so that the short side wall 22d will be flush with the short side wall 21d. An area of the lower front surface 21e of the lower housing portion 21 on which the upper housing portion 22 is formed is uncovered.

Connecting portions of an output wiring member 63, a positive electrode wiring member 61, a negative electrode wiring member 62, a positive electrode wiring member 61, and a negative electrode wiring member 62 are located on the upper front surface 22e from the short side wall 22b to the short side wall 22d (in the +X direction). The output wiring member 63, the positive electrode wiring member 61, the negative electrode wiring member 62, the positive electrode wiring member 61, and the negative electrode wiring member 62 are also bent with respect to the upper front surface 22e. In this case, as illustrated in FIG. 1, the output wiring member 63 is bent in the −Y direction. The positive electrode wiring member 61, the negative electrode wiring member 62, the positive electrode wiring member 61, and the negative electrode wiring member 62 are bent in the +Y direction. Furthermore, nuts are also housed in the upper front surface 22e opposite the wiring member 63, the wiring member 61, the wiring member 62, the wiring member 61, and the wiring member 62.

The case 20 is made of a thermoplastic resin such as polyphenylene sulfide resin, polybutylene terephthalate resin, polybutylene succinate resin, polyamide resin, or acrylonitrile butadiene styrene resin.

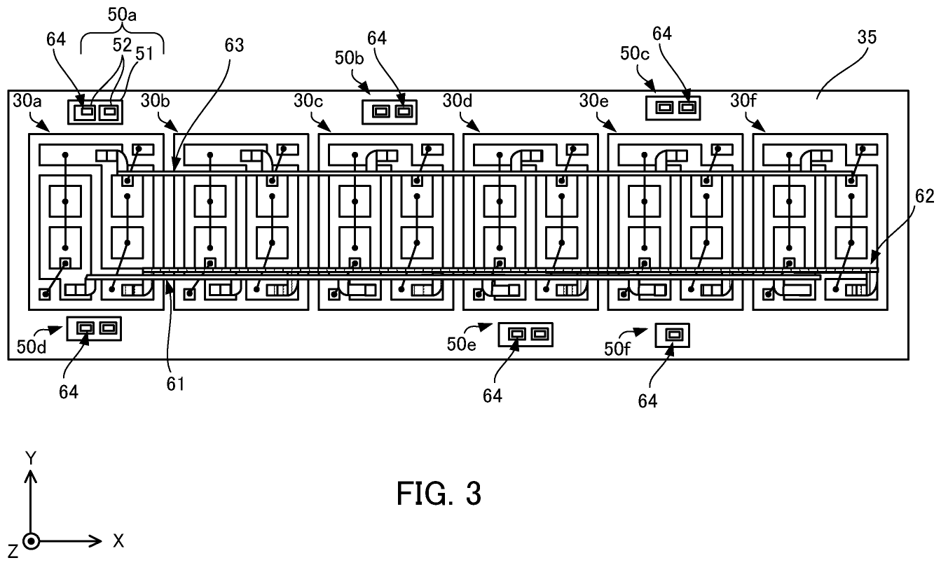

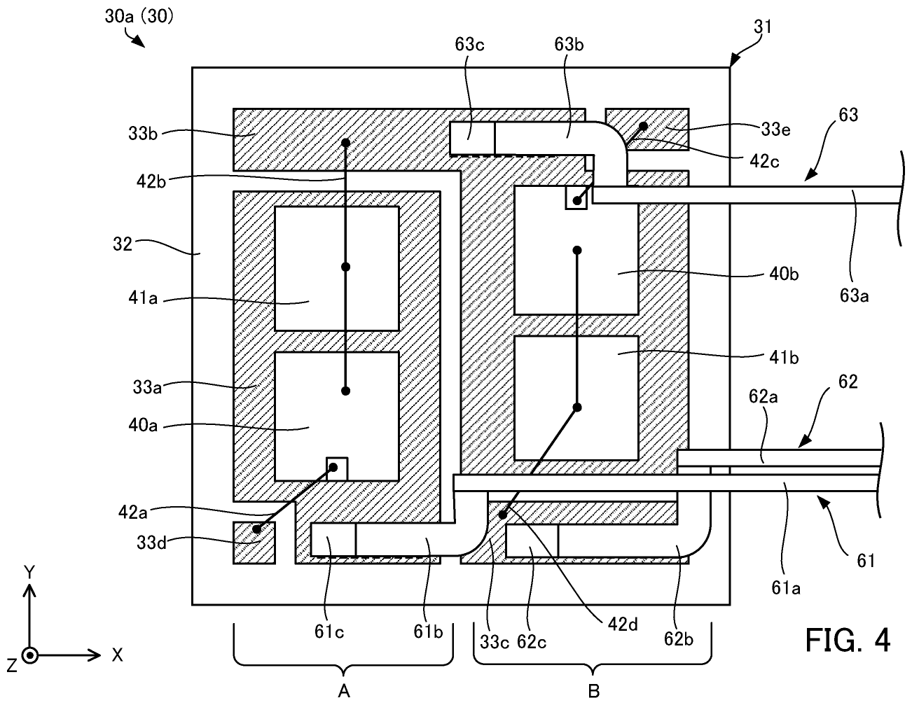

Components housed in the case 20 of the power converter 10 will now be described with reference to FIG. 3 and FIG. 4. FIG. 3 is a plan view of the inside of the power converter according to the first embodiment. FIG. 4 is a plan view of a semiconductor unit included in the power converter according to the first embodiment. FIG. 3 and FIG. 4 illustrate the power converter 10 of FIG. 1 from which the case 20 is removed. FIG. 4 illustrates the leftmost semiconductor unit 30a of the semiconductor units 30a through 30f illustrated in FIG. 3.

As illustrated in FIG. 3, the power converter 10 includes a heat radiation base plate 35, the semiconductor units 30a through 30f located over the heat radiation base plate 35, and control wiring units 50a through 50f. The semiconductor units 30a through 30f have the same structure. If no distinctions are made among the semiconductor units 30a through 30f, then they will be indicated by the semiconductor units 30. Furthermore, if no distinctions are made among the control wiring units 50a through 50f, then they will be indicated by the control wiring units 50. The power converter 10 includes the positive electrode wiring member 61, the negative electrode wiring member 62, and the output wiring member 63 electrically connected to the semiconductor units 30. With the power converter 10, the case 20 is fixed on the heat radiation base plate 35. The semiconductor units 30 and the control wiring units 50 over the heat radiation base plate 35 are covered with the case 20.

The heat radiation base plate 35 is made of metal, such as aluminum, iron, silver, copper, magnesium, or an alloy containing at least one of them, having high thermal conductivity. In order to improve corrosion resistance, plating treatment may be performed on the surface of the heat radiation base plate 35. At this time, nickel, a nickel-phosphorus alloy, a nickel-boron alloy, or the like is used as a plating material. A cooler (not illustrated) may be fixed on the back surface of the heat radiation base plate 35 of the power converter 10 with thermal grease therebetween to improve the heat dissipation property. In this case, the cooler is made of aluminum, iron, silver, copper, an alloy containing at least one of them, or the like which has high thermal conductivity. Furthermore, a fin, a heat sink made up of a plurality of fins, a water-cooling cooler, or the like may be used as the cooler. The thermal grease is, for example, silicone with which a metal oxide filler is mixed.

In addition, the heat radiation base plate 35 and the cooler may be integrally formed. In that case, the heat radiation base plate 35 and the cooler are made of aluminum, iron, silver, copper, or an alloy containing at least one of them which has high thermal conductivity. In this case, in order to improve corrosion resistance, plating treatment may be performed on the surface of the heat radiation base plate 35 integrally formed with the cooler. At this time, nickel, a nickel-phosphorus alloy, a nickel-boron alloy, or the like is used as a plating material.

As illustrated in FIG. 4, the semiconductor unit 30 includes an insulated circuit board 31 and a first semiconductor chip 40a, a second semiconductor chip 41a, a first semiconductor chip 40b, and a second semiconductor chip 41b arranged over the insulated circuit board 31. With the semiconductor unit 30, the insulated circuit board 31 and the first semiconductor chip 40a, the second semiconductor chip 41a, the first semiconductor chip 40b, and the second semiconductor chip 41b are electrically connected properly by bonding wires 42a through 42d, respectively and a first arm block A and a second arm block B are formed.

Each of the first semiconductor chips 40a and 40b and the second semiconductor chips 41a and 41b includes a power device element made of silicon, silicon carbide, or gallium nitride. Furthermore, for example, the thickness of the first semiconductor chips 40a and 40b and the second semiconductor chips 41a and 41b is larger than or equal to 40 μm and smaller than or equal to 250 μm. The power device element is a switching element or a diode element.

Each of the first semiconductor chips 40a and 40b includes a switching element such as an IGBT or a power MOSFET. If each of the first semiconductor chips 40a and includes an IGBT, then each of the first semiconductor chips 40a and 40b has on the back surface a collector electrode as a main electrode and has on the front surface a gate electrode as a control electrode and an emitter electrode as a main electrode. In addition, if each of the first semiconductor chips 40a and 40b includes a power MOSFET, then each of the first semiconductor chips 40a and 40b has on the back surface a drain electrode as a main electrode and has on the front surface a gate electrode as a control electrode and a source electrode as a main electrode.

Each of the second semiconductor chips 41a and 41b includes a diode element such as a free wheeling diode (FWD). The FWD is a Schottky barrier diode (SBD), a P-intrinsic-N (PiN) diode, or the like. In this case, each of the second semiconductor chips 41a and 41b has on the back surface a cathode electrode as a main electrode and has on the front surface an anode electrode as a main electrode. That is to say, with the second semiconductor chips 41a and 41b, the main electrode on the front surface and the main electrode on the back surface are conductive portions.

The back surfaces of the first semiconductor chips 40a and 40b and the second semiconductor chips 41a and 41b are bonded mechanically and electrically to wiring boards 33a and 33b with a bonding member (not illustrated). The bonding member is solder, a brazing filler metal, or a sintered metal body. Pb-free solder is used as the solder. The Pb-free solder contains as a main ingredient an alloy containing at least two of tin, silver, copper, zinc, antimony, indium, bismuth, and the like. Furthermore, the solder may contain an additive such as nickel, germanium, cobalt, or silicon. The solder containing an additive improves wettability, a gloss, and bonding strength and reliability is improved. The brazing filler metal contains as a main ingredient at least one of an aluminum alloy, a titanium alloy, a magnesium alloy, a zirconium alloy, a silicon alloy, and the like. The sintered metal body contains as a main ingredient, for example, silver and a silver alloy.

Furthermore, reverse conducting (RC)-IGBTs each having both of the function of an IGBT and the function of an FWD may be used in place of the first semiconductor chips 40a and 40b and the second semiconductor chips 41a and 41b.

The insulated circuit boards 31 are arranged in line over the front surface of the heat radiation base plate 35 along the long sides of the heat radiation base plate 35. The insulated circuit boards 31 are bonded to the front surface of the heat radiation base plate 35 with, for example, the above bonding member (not illustrated) therebetween.

Each insulated circuit board 31 includes an insulating plate 32 and a metal plate (not illustrated) formed on the back surface of the insulating plate 32. Furthermore, each insulated circuit board 31 includes wiring boards 33a through 33e formed over the front surface of the insulating plate 32. If no special distinctions are made among the wiring boards 33a through 33e, hereinafter they will be indicated by the wiring boards 33.

The insulating plate 32 and the metal plate are rectangular in plan view. Furthermore, corner portions of the insulating plate 32 and the metal plate may be R-chamfered or C-chamfered. The size of the metal plate is smaller in plan view than that of the insulating plate 32 and the metal plate is formed inside the insulating plate 32.

The insulating plate 32 contains as a main ingredient a material, such as a ceramic or insulating resin, having an insulating property and high thermal conductivity. The ceramic is aluminum oxide, aluminum nitride, silicon nitride, or the like. The insulating resin is a paper phenolic board, a paper epoxy board, a glass composite board, a glass epoxy board, or the like. For example, the thickness of the insulating plate 32 is greater than or equal to 0.2 mm and smaller than or equal to 2.5 mm.

The wiring boards 33a through 33e are conductive portions and contain as a main ingredient metal, such as copper, aluminum, or an alloy containing as a main ingredient at least one of them, having good electrical conductivity. Furthermore, the thickness of the wiring boards 33a through 33e is greater than or equal to 0.1 mm and smaller than or equal to 2.0 mm. In order to improve corrosion resistance, plating treatment may be performed on the surfaces of the wiring boards 33a through 33e. At this time, nickel, a nickel-phosphorus alloy, a nickel-boron alloy, or the like is used as a plating material. The wiring boards 33a through 33e illustrated in FIG. 4 are taken as an example. The number, shape, size, or the like of the wiring boards 33 may be properly selected as needed.

The wiring board 33a corresponds to a collector pattern of the first arm block A. The input electrode (collector electrode) and the output electrode (cathode electrode) formed on the back surfaces of the first semiconductor chip 40a and the second semiconductor chip 41a, respectively, are bonded to the wiring board 33a with the above described bonding member therebetween. The wiring board 33a is approximately rectangular and a portion of the wiring board 33a to which a leg portion 61c of the positive electrode wiring member 61 is bonded protrudes to the downside in FIG. 4.

The wiring board 33d corresponds to a control pattern of the first arm block A. The bonding wire 42a connected to the control electrode of the first semiconductor chip 40a is connected to the wiring board 33d. Furthermore, the wiring board 33d is electrically connected to a control wiring unit 50 (control wiring unit 50d for the semiconductor unit 30a), which is not illustrated, by a bonding wire (not illustrated).

The wiring board 33b corresponds to an emitter pattern of the first arm block A and a collector pattern of the second arm block B. The bonding wire 42b connected to the output electrode (emitter electrode) of the first semiconductor chip 40a over the wiring board 33a and the input electrode (anode electrode) of the second semiconductor chip 41a over the wiring board 33a is connected to the wiring board 33b. Furthermore, the input electrode (collector electrode) formed on the back surface of the first semiconductor chip 40b and the output electrode (cathode electrode) formed on the back surface of the second semiconductor chip 41b are bonded to the wiring board 33b with the above described bonding member therebetween. The wiring board 33b is approximately rectangular and a portion of the wiring board 33b on the upper side of FIG. 4 protrudes. The wiring board 33b is located side by side with the wiring board 33a. In addition, the wiring board 33b is electrically connected to a control wiring unit 50 (control wiring unit for the semiconductor unit 30a) by a bonding wire (not illustrated).

The wiring board 33e corresponds to a control pattern of the second arm block B. The bonding wire 42c connected to the control electrode of the first semiconductor chip 40b is connected to the wiring board 33e.

The wiring board 33c corresponds to an emitter pattern of the second arm block B. The bonding wire 42d connected to the output electrode (emitter electrode) of the first semiconductor chip 40b is connected to the wiring board 33c. The wiring board 33c is located on the lower side of the wiring board 33b of FIG. 4. A leg portion 62c of the negative electrode wiring member 62 is bonded to the wiring board 33c.

The area of the metal plate formed on the back surface of the insulating plate 32 is smaller than that of the insulating plate 32 and is larger than that of an area in which the wiring boards 33a through 33e are formed. The metal plate is rectangular. This is the same with the insulating plate 32. Furthermore, the corner portions of the metal plate may be R-chamfered or C-chamfered. The size of the metal plate is smaller than that of the insulating plate 32 and the metal plate is formed on the entire back surface except an edge portion of the insulating plate 32. The metal plate contains as a main ingredient metal, such as copper, aluminum, or an alloy containing at least one of them, having high thermal conductivity. In addition, the thickness of the metal plate is greater than or equal to 0.1 mm and smaller than or equal to 2.5 mm. In order to improve the corrosion resistance of the metal plate, plating treatment may be performed. At this time, nickel, a nickel-phosphorus alloy, a nickel-boron alloy, or the like is used as a plating material.

A direct copper bonding (DCB) substrate, an active metal brazed (AMB) substrate, a resin insulating substrate, or the like may be used as each insulated circuit board 31 having the above structure.

The positive electrode wiring member 61, the negative electrode wiring member 62, and the output wiring member 63 are made of metal, such as silver, copper, nickel, or an alloy containing at least one of them, having good electrical conductivity. In order to improve corrosion resistance, plating treatment may be performed on the surfaces of the control wiring members 64. At this time, nickel, a nickel-phosphorus alloy, a nickel-boron alloy, or the like is used as a plating material. The positive electrode wiring member 61, the negative electrode wiring member 62, and the output wiring member 63 are connected electrically and mechanically to the semiconductor units 30a through 30f located in line over the heat radiation base plate 35.

The positive electrode wiring member 61 includes a body portion 61a, connecting portion 61b, and leg portion 61c. The positive electrode wiring member 61 includes the leg portions 61c (and the connecting portions 61b) in positions corresponding to the semiconductor units 30a through 30f to which the positive electrode wiring member 61 is connected. The positive electrode wiring member 61 has a connection portion (not illustrated) in a position in which the positive electrode wiring member 61 is exposed from the case 20. Furthermore, the negative electrode wiring member 62 and the output wiring member 63 also include body portions 62a and 63a, connecting portions 62b and 63b, and leg portions 62c and 63c, respectively.

The body portions 61a, 62a, and 63a have the shape of a flat plate and extend in the wiring direction (in the longitudinal direction of the heat radiation base plate 35) at a determined height from the front surfaces of the semiconductor units 30a through 30f (insulated circuit boards 31) located in one direction. The leg portions 61c, 62c, and 63c are bonded to the wiring boards 33a, 33c, and 33b, respectively, of each insulated circuit board 31. The connecting portions 61b, 62b, and 63b are integrally connected to the body portions 61a, 62a, and 63a and the leg portions 61c, 62c, and 63c, respectively. Accordingly, the connecting portions 61b, 62b, and 63b electrically connect the body portions 61a, 62a, and 63a and the leg portions 61c, 62c, and 63c, respectively. External terminals (not illustrated) are connected to the body portions 61a, 62a, and 63a. The external terminals are exposed from the upper front surface 22e of the upper housing portion 22 of the case 20.

The control wiring units 50a, 50b and 50c are located over the heat radiation base plate 35 and are located over the semiconductor units 30a, 30c, and 30e, respectively, (in the +Y direction) in FIG. 3. The control wiring units 50d, 50e, and 50f are located over the heat radiation base plate 35 and are located under the semiconductor units 30a, 30d, and 30e, respectively, (in the −Y direction) in FIG. 3.

Each of the above control wiring units 50 includes an insulating plate 51, a wiring board 52 located over the insulating plate 51, a metal plate (not illustrated) formed on the back surface of the insulating plate 51, and the control wiring member 64 bonded to the wiring board 52. With the control wiring unit 50f of the control wiring units 50, the wiring board 52 and the control wiring member 64 are formed. With the other control wiring units 50, the two wiring boards 52 and the two control wiring members 64 are formed.

The insulating plates 51 are made of a ceramic having high thermal conductivity. The ceramic may be a composite material containing as a main ingredient, aluminum oxide and zirconium oxide added to the aluminum oxide, a material containing silicon nitride as a main ingredient, or the like. Furthermore, the thickness of the insulating plates 51 is greater than or equal to 0.5 mm and smaller than or equal to 2.0 mm. The insulating plates 51 are rectangular in plan view. In addition, corner portions of the insulating plates 51 may be R-chamfered or C-chamfered.

The wiring boards 52 are made of metal, such as silver, copper, nickel, or an alloy containing at least one of them, having good electrical conductivity. Furthermore, the thickness of the wiring boards 52 is greater than or equal to 0.5 mm and smaller than or equal to 1.5 mm. In order to improve corrosion resistance, plating treatment may be performed on the surfaces of the wiring boards 52. At this time, nickel, a nickel-phosphorus alloy, a nickel-boron alloy, or the like is used as a plating material. A metal layer is formed on the front surface of the insulating plates 51 and treatment, such as etching, is performed on the metal layer. By doing so, the wiring boards 52 are obtained. Alternatively, the wiring boards 52 cut in advance out of a metal plate may be pressure-bonded to the front surfaces of the insulating plates 51. The wiring boards 52 illustrated in FIG. 3 are taken as an example. The number, shape, size, or the like of the wiring boards 52 may be properly selected as needed.

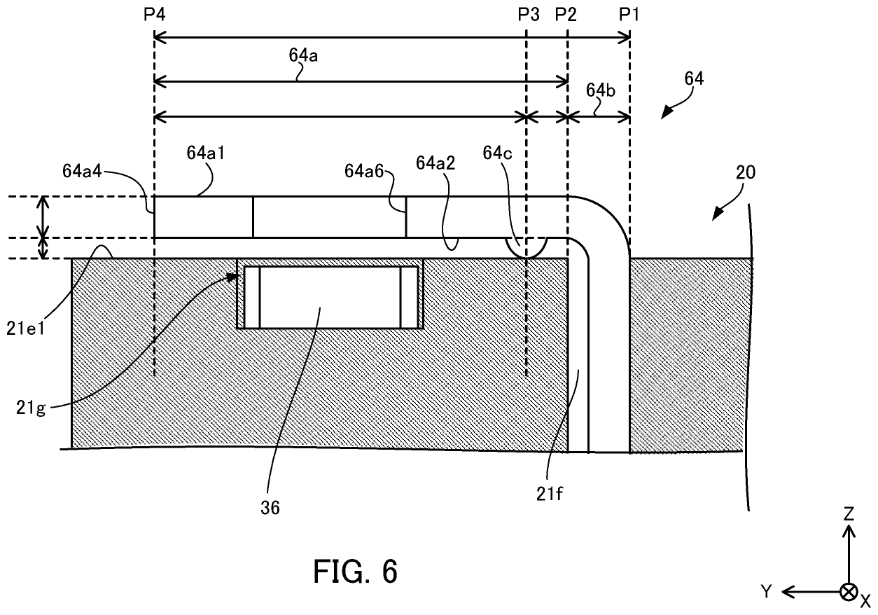

The control wiring members 64 are made of metal, such as silver, copper, nickel, or an alloy containing at least one of them, having good electrical conductivity. In order to improve corrosion resistance, plating treatment may be performed on the surfaces of the control wiring members 64. At this time, nickel, a nickel-phosphorus alloy, a nickel-boron alloy, or the like is used as a plating material. The control wiring members 64 have the shape of, for example, a stripe and have approximately uniform thickness as a whole. Furthermore, the thickness of the control wiring members 64 is smaller than the opening width (in the ±Y direction) of an outlet 21f of the case 20 described later (see FIG. 6. The opening width corresponds to the length from a point P1 to a point P2). For example, the thickness of the control wiring members 64 is greater than or equal to 60 percent of the opening width and smaller than or equal to 90 percent of the opening width.

A lower end portion of each control wiring member 64 is bonded to the wiring board 52 with the above described bonding member. Alternatively, ultrasonic bonding may be performed. When the case 20 is fixed, the control wiring member 64 is drawn out from (inserted into) the outlet 21f of the case 20 and a portion of the control wiring member 64 drawn out from the outlet 21f of the case 20 is bent. The details of the control wiring member 64 fixed to the case 20 will be described later.

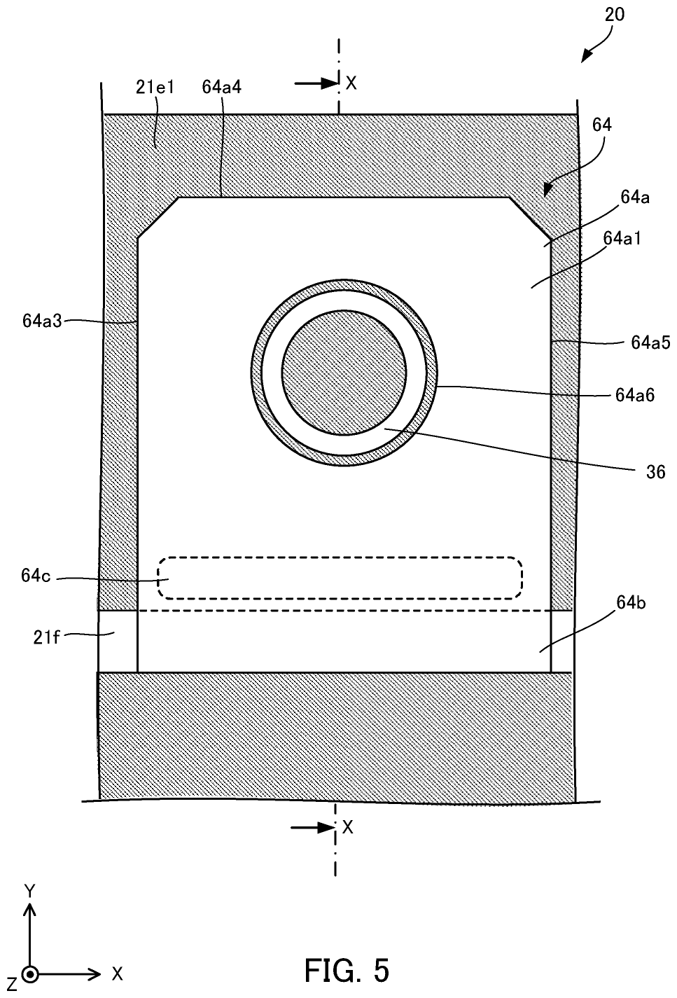

The details of the control wiring member 64 exposed from the case 20 will now be described with reference to FIG. 5 and FIG. 6. FIG. 5 is a plan view of the wiring member included in the power converter according to the first embodiment. FIG. 6 is a sectional view of the wiring member included in the power converter according to the first embodiment. FIG. 5 and FIG. 6 illustrate the control wiring member 64 exposed from the control terminal area 21e1 illustrated in FIG. 1. The control wiring members 64 are exposed not only from the control terminal area 21e1 but also from the control terminal areas 21e2 through 21e6. FIG. 6 is a sectional view taken along the dot-dash line X-X of FIG. 5. In FIG. 6, it is assumed that an end portion in the −Y direction of the outlet 21f is the point P1 and that an end portion in the +Y direction of the outlet 21f is the point P2. Furthermore, it is assumed that the position of the center of a bottom of a spacer 64c which is in contact with the control terminal area 21e1 is a point P3. It is assumed that the position of an end side 64a4 of an external connection portion (draw-out portion) 64a is a point P4. In FIG. 6, an end portion in the −Y direction of the external connection portion 64a is also superimposed over the point P2. However, the end portion in the −Y direction of the external connection portion 64a may be situated in the +Y direction of the point P2, depending on how a bending portion 64b bends. For example, the external connection portion 64a is formed by a portion (drawn-out portion) of the control wiring member 64 that extends out from the outlet 21f at the outlet opening, and is bent at the outlet opening toward the lower front surface 21e1 of the case 20 so that the drawn-out portion extends in a direction approximately parallel to the lower front surface 21e1.

The control wiring member 64 includes the external connection portion 64a corresponding to an end portion and the bending portion 64b which connects the external connection portion 64a and the rest of the control wiring member 64 and which bends. The control wiring member 64 bends from the bending portion 64b at the outlet 21f and the external connection portion 64a extends approximately parallel to the control terminal area 21e1 of the case 20. The external connection portion 64a may be inclined toward the control terminal area 21e1 of the case 20 so that an end portion (end side 64a4) of the external connection portion 64a will approach the control terminal area 21e1 (be situated below the bending portion 64b).

In FIG. 6, the control wiring member 64 is in contact with the outlet 21f on the side of the inside of the case 20 (at the point P1 in the −Y direction). The control wiring member 64 may be in contact with the outlet 21f on the side of the outside of the case 20 (at the point P2 in the +Y direction). Moreover, it may be that the control wiring member 64 will not be in contact with the point P1 or the point P2 of the outlet 21f. However, it is preferable that the control wiring member 64 be in contact with the point P1 or the point P2 of the outlet 21f. The reason for this is as follows. The control wiring member 64 may be bent stably at the time of bending described later and movement of the control wiring member 64 after the bending in the outlet 21f is decreased.

The external connection portion 64a is drawn out from the outlet 21f in the control terminal area 21e1 of the case 20 and is approximately parallel to the control terminal area 21e1 of the case 20. That is to say, there is a gap between a back surface 64a2 of the external connection portion 64a and the control terminal area 21e1. The back surface 64a2 of the external connection portion 64a is also opposed to the control terminal area 21e1 of the case 20.

The end portion of the external connection portion 64a is surrounded on three sides by a side 64a3, an end side 64a4, and a side 64a5. That is to say, the end side 64a4 is perpendicular to a direction in which the external connection portion 64a extends (in which the external connection portion 64a is drawn out from the outlet 21f) and the sides 64a3 and 64a5 are parallel to the direction in which the external connection portion 64a extends. Portions in which the sides 64a3 and 64a5 are connected to the end side 64a4 may be R-chamfered or C-chamfered. A fastening hole 64a6 which pierces the external connection portion 64a from a front surface 64a1 to the back surface 64a2 is made. The fastening hole 64a6 may be made in a central portion of the external connection portion 64a.

Furthermore, the spacer 64c is formed on the back surface (first surface) 64a2 of the external connection portion 64a. The spacer 64c is in contact with the control terminal area 21e1. Alternatively, the spacer 64c may be put between the back surface 64a2 and the control terminal area 21e1. The spacer 64c (point P3) is formed between an end portion (point P2) on the side of the bending portion 64b of the back surface 64a2 opposite the control terminal area 21e1 of the case 20 and the fastening hole 64a6. It is preferable that the spacer 64c be formed in the vicinity of the outlet 21f on the back surface 64a2 of the external connection portion 64a. For example, the vicinity of the outlet 21f means an area about the thickness of the control wiring member 64 distant from the end portion (point P2) of the external connection portion 64a.

For example, the spacer 64c continuously extends straight in plan view between the sides 64a3 and 64a5 with respect to the back surface 64a2 of the external connection portion 64a. The spacer 64c is semicircular in side view. That is to say, the spacer 64c in the first embodiment is semicylindrical. Furthermore, for example, the spacer 64c may be rectangular or triangular in side view. That is to say, the spacer 64c may have the shape of a quadrangular prism or a triangular prism. In other words, the spacer 64c has in side view a shape which is such that the spacer 64c is put between the back surface 64a2 of the external connection portion 64a and the control terminal area 21e1. In addition, it may be that the spacer 64c will not continuously extend straight. For example, a plurality of spacers 64c which have the shape of a semisphere, a quadrangular prism, a cone, or a pyramid may discontinuously be formed straight. Moreover, in these cases and in the case of FIG. 5 and FIG. 6, spacers 64c may be formed in a row or in more than one row that are arranged in the X direction. Furthermore, the spacer 64c having the above shape may be formed on the external connection portion 64a by welding, pressure welding, brazing, or the like.

A nut housing portion 21g in which a nut 36 is housed is formed in the control terminal area 21e1 of the case 20. The nut housing portion 21g is formed in a position in the control terminal area 21e1 opposite the fastening hole 64a6 of the external connection portion 64a. The bottom of the nut housing portion 21g is situated under (in the −Z direction of) the control terminal area 21e1 and is approximately parallel to the control terminal area 21e1. The diameter and depth of the nut housing portion 21g are such that the nut 36 is completely housed. The diameter of the fastening hole 64a6 of the external connection portion 64a is about 60 percent of the diameter of the nut housing portion 21g. Accordingly, the fastening hole 64a6 of the external connection portion 64a is opposite the nut 36 housed in the nut housing portion 21g.

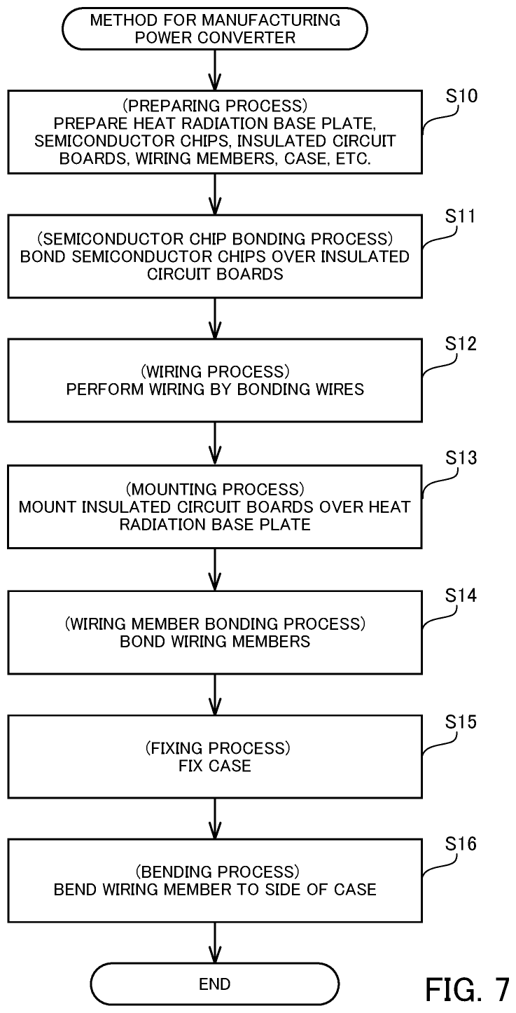

A method for manufacturing (assembling) the above power converter 10 will now be described with reference to FIG. 7. FIG. 7 is a flow chart illustrative of a method for manufacturing the power converter according to the first embodiment.

First a preparing process for preparing components of the power converter 10 is performed (step S10). Components prepared in the preparing process are the heat radiation base plate 35, the first semiconductor chips 40a and 40b, the second semiconductor chips 41a and 41b, the insulated circuit boards 31, the various wiring members 61 through 64, the case 20, and the like. Components not described here are also prepared as needed. Furthermore, as described later, forming the spacer 64c on the wiring member 64 may be included in the preparing process.

Next, a semiconductor chip bonding process for bonding the first semiconductor chips 40a and 40b and the second semiconductor chips 41a and 41b over the insulated circuit board 31 is performed (step S11). The first semiconductor chip 40a and the second semiconductor chip 41a are bonded to the wiring board 33a of the insulated circuit board 31. The first semiconductor chip 40b and the second semiconductor chip 41b are bonded to the wiring board 33b.

Next, a wiring process for performing wiring by bonding wires is performed (step S12). For the insulated circuit board 31 over which the first semiconductor chips 40a and 40b and the second semiconductor chips 41a and 41b are bonded, the wiring board 33d and the control electrode of the first semiconductor chip 40a are directly connected by the bonding wire 42a. The output electrode of the first semiconductor chip 40a, the input electrode of the second semiconductor chip 41a, and the wiring board 33b are directly connected by the bonding wire 42b. Furthermore, the wiring board 33e and the control electrode of the first semiconductor chip 40b are directly connected by the bonding wire 42c. The output electrode of the first semiconductor chip 40b, the input electrode of the second semiconductor chip 41b, and the wiring board 33c are directly connected by the bonding wire 42d. The needed number of the semiconductor units 30 are assembled in this way.

In addition, at this time, the control wiring unit 50 is also assembled. A substrate including the insulating plate 51, the wiring board 52 located over the insulating plate 51, the metal plate (not illustrated) formed on the back surface of the insulating plate 51 is prepared in advance. A lower end portion of the wiring member 64 is bonded to the wiring board 52 of the substrate. At this time, the wiring member 64 is in a state in which it extends vertically upward with respect to the wiring board 52. The needed number of the control wiring units 50 are assembled in this way.

Next, a mounting process for mounting the semiconductor units 30 (insulated circuit boards 31) over the heat radiation base plate 35 is performed (step S13). The semiconductor units 30 are mounted over a plurality of mounting areas set on the front surface of the heat radiation base plate 35 in the longitudinal direction of the heat radiation base plate 35 with a bonding member therebetween and are bonded to the heat radiation base plate 35 with the bonding member. Furthermore, similarly, the control wiring units 50 are mounted over the heat radiation base plate 35 and are bonded to the heat radiation base plate 35.

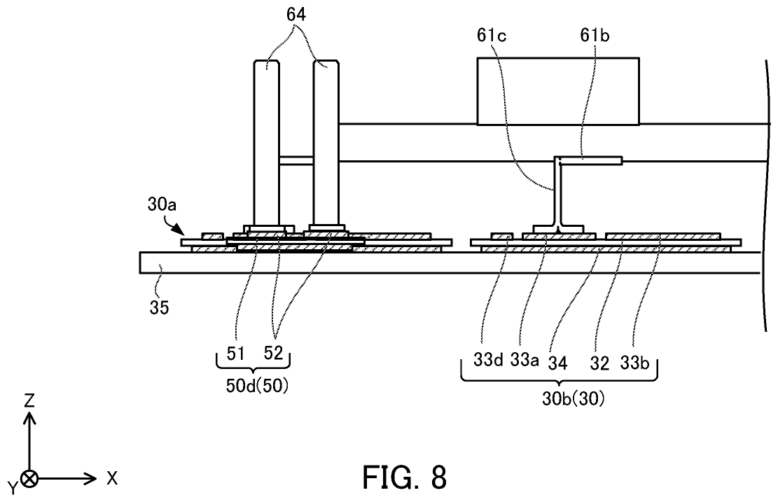

Next, a wiring member bonding process for bonding the wiring members 61 through 63 to the semiconductor units 30 arranged over the heat radiation base plate 35 is performed (step S14). The wiring member bonding process will be described with reference to FIG. 8. FIG. 8 illustrates the wiring member bonding process included in the method for manufacturing the power converter according to the first embodiment. FIG. 8 is a side view of the leftmost end of the heat radiation base plate 35 after the wiring member bonding process including the wiring members 61 through 63.

The wiring members 61, 62, and 63 are fixed to the heat radiation base plate 35 over which the semiconductor units 30 and the control wiring units 50 are mounted in step S13. At this time, the leg portion 61c of the wiring member 61 is bonded to the wiring board 33a of the insulated circuit board 31. The leg portion 62c of the wiring member 62 is bonded to the wiring board 33c of the insulated circuit board 31. The leg portion 63c of the wiring member 63 is bonded to the wiring board 33b of the insulated circuit board 31. As a result, as illustrated in FIG. 8, the wiring members 61, 62, and 63 are bonded to the semiconductor unit 30.

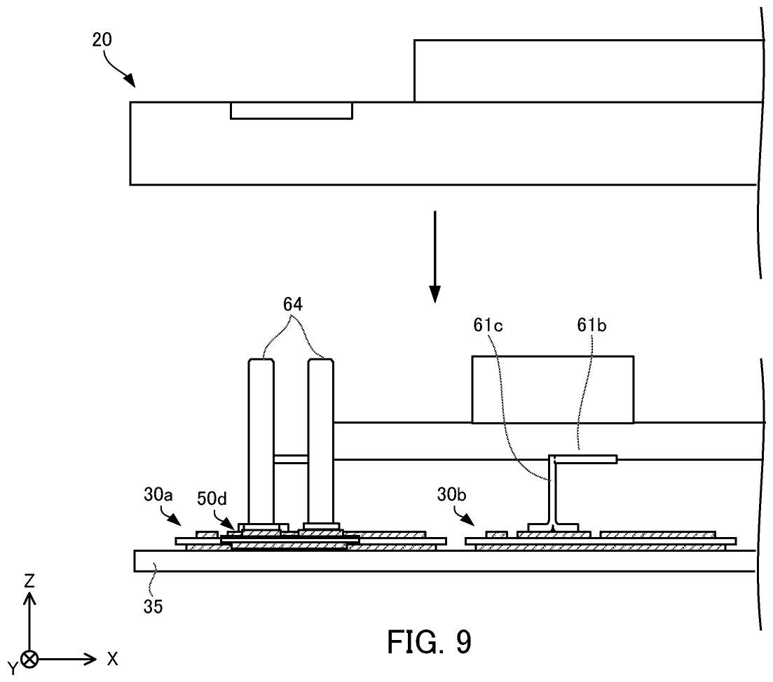

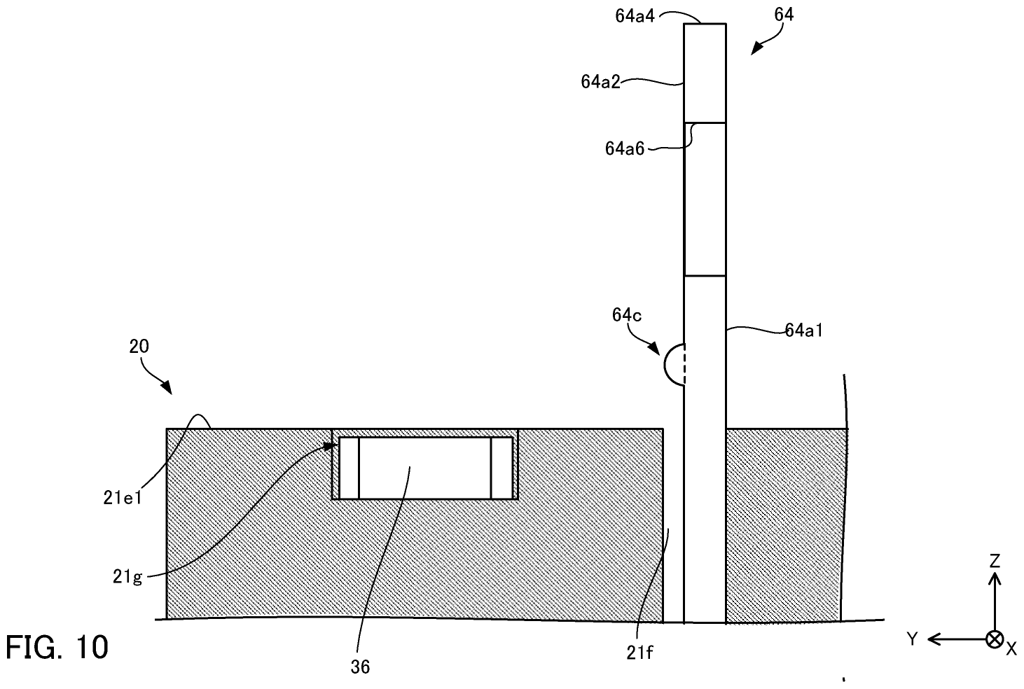

Next, a fixing process for fixing the case 20 to the heat radiation base plate 35 over which the semiconductor units 30 to which the wiring members 61, 62, and 63 are bonded and the control wiring units 50 are mounted is performed (step S15). The fixing process will be described with reference to FIG. 9 and FIG. 10. FIG. 9 illustrates the fixing process (under fixing) included in the method for manufacturing the power converter according to the first embodiment. FIG. 10 illustrates the fixing process (after fixing) included in the method for manufacturing the power converter according to the first embodiment. FIG. 9 is a side view of the leftmost end of the heat radiation base plate 35 in the fixing process including the wiring members 61 through 63. FIG. 10 corresponds to FIG. 6 and is a sectional view of the wiring member 64 drawn out from the control terminal area 21e1 after fixing the case 20.

As illustrated in FIG. 9, the case 20 is fixed from above to the heat radiation base plate 35 over which the semiconductor units 30 to which the wiring members 61, 62, and 63 are bonded and the control wiring units 50 are mounted. At this time, an adhesive is applied in advance to bottom portions of the long side wall 21a, the short side wall 21b, the long side wall 21c, and the short side wall 21d of the case 20 and the case 20 is bonded to an outer peripheral portion of the heat radiation base plate 35.

As illustrated in FIG. 10, for example, when the case 20 is fixed in this way, the wiring member 64 extends vertically upward (in the +Z direction) from the outlet 21f in the control terminal area 21e1 of the case 20. For the control terminal area 21e2 through 21e6 (not illustrated), the wiring member 64 extends vertically upward from the outlet 21f. This is the same with FIG. 10.

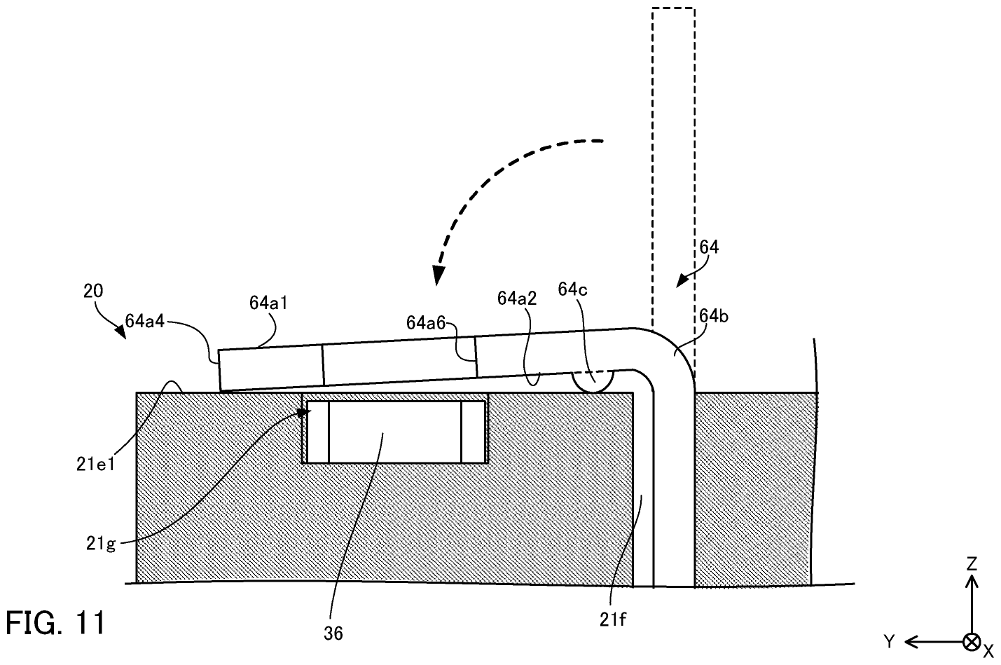

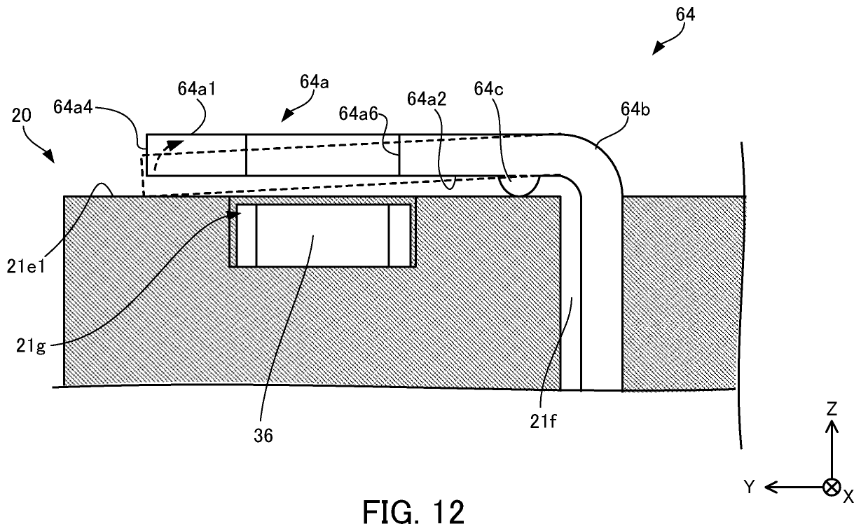

Next, a bending process for bending the wiring member 64 to the side of the case 20 is performed (step S16). The bending process will be described with reference to FIG. 11 and FIG. 12. FIGS. 11 and 12 illustrate the bending process included in the method for manufacturing the power converter according to the first embodiment.

As illustrated in FIG. 11, the front surface 64a1 of the wiring member 64 extending vertically upward from the outlet 21f in the control terminal area 21e1 of the case 20 is pressed toward the control terminal area 21e1 of the case 20. By doing so, the wiring member 64 bends with a portion near the outlet 21f as a fulcrum and the external connection portion 64a falls toward the control terminal area 21e1.

When the front surface 64a1 of the wiring member 64 is continuously pressed in the same direction, the spacer 64c of the external connection portion 64a comes in contact with the control terminal area 21e1. As illustrated in FIG. 11, when the front surface 64a1 of the wiring member 64 is pressed further, the end side 64a4 of the external connection portion 64a comes in contact with the control terminal area 21e1 with the spacer 64c as a fulcrum.

After that, pressure applied to the wiring member 64 is released. The external connection portion 64a of the wiring member 64 pressure on which is released attempts to return to the original position to restore a state in which the wiring member 64 is not yet bent. Just after the pressure applied to the wiring member 64 is released, the external connection portion 64a is inclined to a degree that the end side 64a4 of the external connection portion 64a comes in contact with the control terminal area 21e1 with the spacer 64c as a fulcrum. Accordingly, it is assumed that the external connection portion 64a attempts to return to the original position. As illustrated in FIG. 12, for example, the external connection portion 64a returns to, at the most, a height at which the external connection portion 64a is approximately parallel to the control terminal area 21e1. That is to say, the external connection portion 64a may be inclined so that the end portion (end side 64a4) of the external connection portion 64a will be apart from the control terminal area 21e1 and so that the end portion (end side 64a4) of the external connection portion 64a will be situated below the bending portion 64b. The above bending process is performed on each wiring member 64. Furthermore, the above bending process may be performed in the same way on the wiring members 61, 62, and 63 not including the spacer 64c. By performing the above processes, the power converter 10 illustrated in FIG. 1 and FIG. 2 is manufactured.

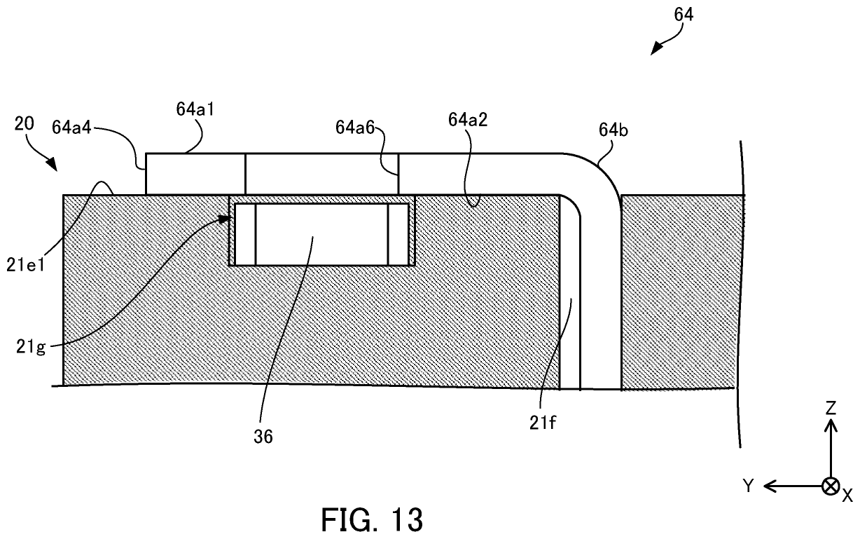

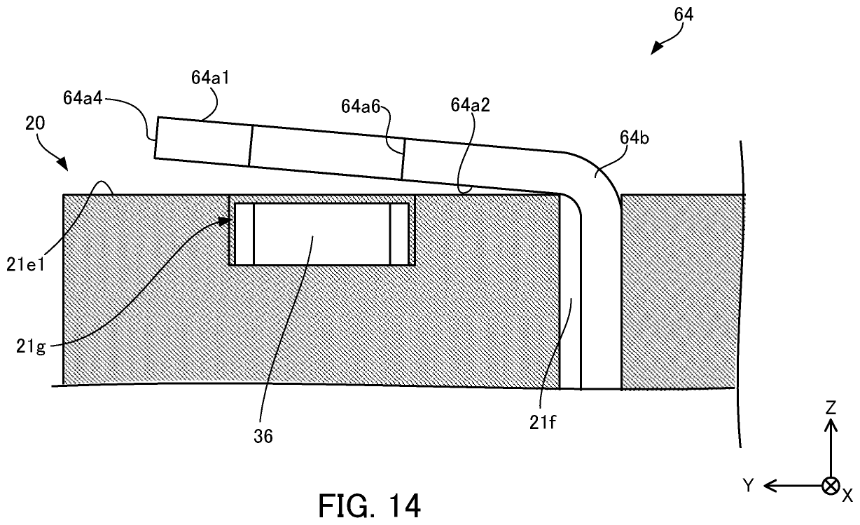

A method for manufacturing a power converter taken as a reference example will now be described. With the power converter taken as a reference example, a spacer is not formed on a wiring member 64. The structure of the power converter taken as a reference example differs from that of the power converter 10 illustrated in FIG. 1 and FIG. 2 only in this respect. The power converter taken as a reference example is also manufactured in accordance with the method illustrated in FIG. 7. Step S16 of FIG. 7 will now be described with reference to FIG. 13 and FIG. 14. FIGS. 13 and 14 illustrate a bending process included in a method for manufacturing the power converter taken as a reference example.

In step S16 of FIG. 7, a front surface 64a1 of the wiring member 64 extending vertically upward from an outlet 21f in a control terminal area 21e1 of a case 20 is pressed toward the control terminal area 21e1 of the case 20. By doing so, as illustrated in FIG. 13, the wiring member 64 bends with a portion near the outlet 21f as a fulcrum and an entire back surface 64a2 of an external connection portion 64a comes in contact with the control terminal area 21e1. After that, pressure applied to the wiring member 64 is released. The external connection portion 64a of the wiring member 64 pressure on which is released attempts to return to the original position to restore a state in which the wiring member 64 is not yet bent. As a result, as illustrated in FIG. 14, the external connection portion 64a of the wiring member 64 is inclined with respect to the control terminal area 21e1 of the case 20 with the outlet 21f as a starting point.

For example, a printed-circuit board is located on the inclined external connection portion 64a of the wiring member 64 and is fastened to the inclined external connection portion 64a with a screw. In this case, a portion near an end side 64a4 of the floating external connection portion 64a strikes against the printed-circuit board made of resin. As a result, the printed-circuit board deforms and may be damaged. This deteriorates the reliability of the power converter.

The above described power converter 10 includes the case 20 having the control terminal area 21e1 in which the outlet 21f is formed and the wiring member 64 drawn out from the outlet 21f and bent to the side of the control terminal area 21e1 with the outlet 21f as a starting point. Furthermore, with the power converter 10, the wiring member 64 includes the spacer 64c formed near the outlet 21f on the back surface 64a2 opposite the control terminal area 21e1 and put between the back surface 64a2 and the control terminal area 21e1. When the external connection portion 64a of the wiring member 64 is pressed toward the control terminal area 21e1 of the case 20 to bend the wiring member 64, the external connection portion 64a of the wiring member 64 is inclined due to the spacer 64c so that the end side 64a4 of the external connection portion 64a will be situated below the bending portion 64b. When pressure applied to the wiring member 64 is released, the external connection portion 64a returns to the original state. At this time, the external connection portion 64a returns to a height at which the external connection portion 64a is approximately parallel to the control terminal area 21e1. Even if a printed-circuit board is located on the external connection portion 64a of the wiring member 64 and is fastened to the external connection portion 64a with a screw, the external connection portion 64a does not strike against the printed-circuit board. As a result, the printed-circuit board does not deform and is properly fastened to the wiring member 64. This suppresses deterioration in the reliability of the power converter 10.

A case where the spacer 64c is formed on the external connection portion 64a of the wiring member 64 by welding, pressure welding, brazing, or the like has been described in the foregoing as an example. Forming the spacer 64c on the external connection portion 64a of the wiring member 64 by a method different from welding, pressure welding, and brazing will now be described as modifications and the spacer 64c of various shapes corresponding to formation methods will be described.

(Modification 1-1)

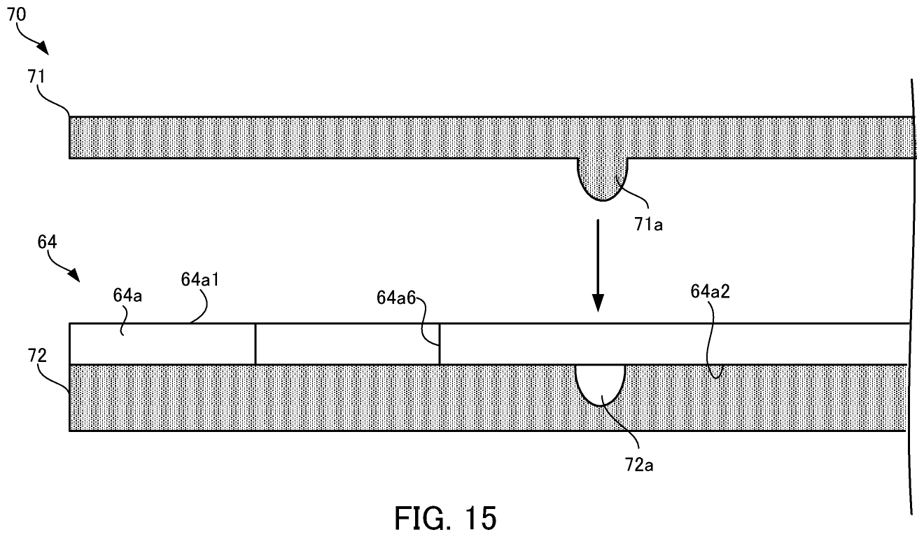

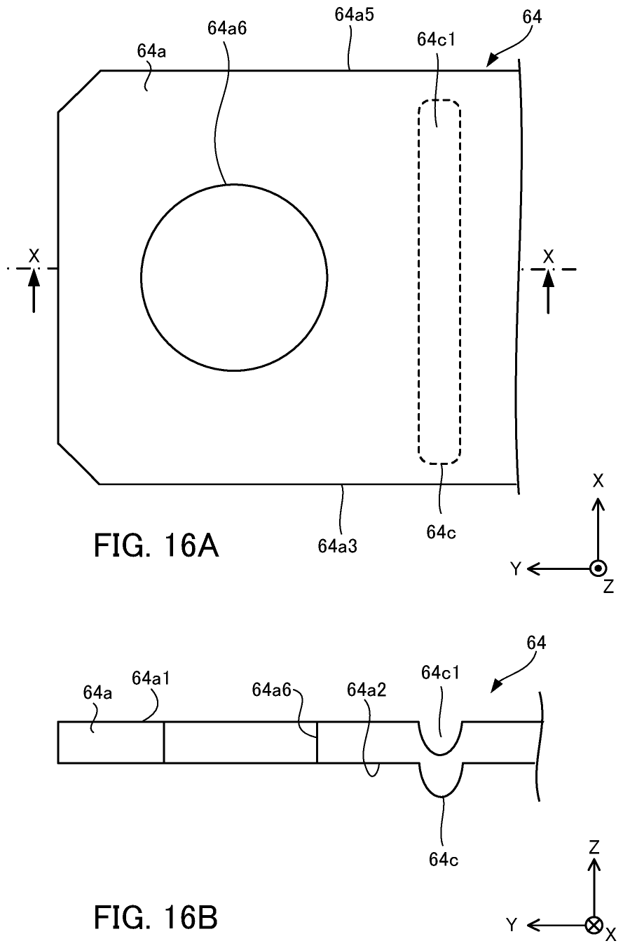

In modification 1-1, a case where the spacer 64c is formed on the wiring member 64 by press working will be described with reference to FIG. 15 and FIGS. 16A and 16B. FIG. 15 illustrates press working of the wiring member included in the method for manufacturing the power converter according to the first embodiment (modification 1-1). FIGS. 16A and 16B illustrate the wiring member included in the power converter according to the first embodiment (modification 1-1). FIG. 16A is a plan view of the external connection portion 64a on which the spacer 64c is formed by press working. FIG. 16B is a sectional view taken along the dot-dash line X-X of FIG. 16A.

The spacer 64c is formed on the external connection portion 64a by press working. First, the wiring member 64 which has the flat front surface 64a1 and the flat back surface 64a2 and on which the spacer 64c is not formed is prepared. The fastening hole 64a6 is made in advance in the wiring member 64. The wiring member 64 is set on a press apparatus 70.

The press apparatus 70 includes a press working jig 71 and a placement table 72. A press portion 71a is formed on the press working jig 71. The shape of the press portion 71a corresponds to that of the spacer 64c to be formed. In the case of modification 1-1, for example, the press portion 71a is semicylindrical. A press receiving portion 72a is formed in a flat placement surface of the placement table 72. The press receiving portion 72a is a recess in the placement surface. The size of the press receiving portion 72a is such that the spacer 64c formed on the wiring member 64 enters the press receiving portion 72a.

At least the external connection portion 64a of the wiring member 64 is set on the placement surface of the placement table 72. Next, the press working jig 71 is positioned so that the press portion 71a will correspond to a desired area of the external connection portion 64a. The press working jig 71 is superimposed over the wiring member 64 and the wiring member 64 is pressed against the placement table 72. Furthermore, the wiring member 64 is taken from the press apparatus 70.

As illustrated in FIGS. 16A and 16B, the spacer 64c is formed on the back surface 64a2 of the external connection portion 64a of the wiring member 64 formed in this way. In addition, a recess (first recess) 64c1 is formed in the front surface (second surface) 64a1 of the external connection portion 64a opposite the spacer 64c. The recess 64c1 is formed by pressing the wiring member 64 with the press portion 71a and the shape of the recess 64c1 corresponds to that of the press portion 71a. This wiring member 64 may be prepared in the preparing process in step S10 of FIG. 7.

(Modification 1-2)

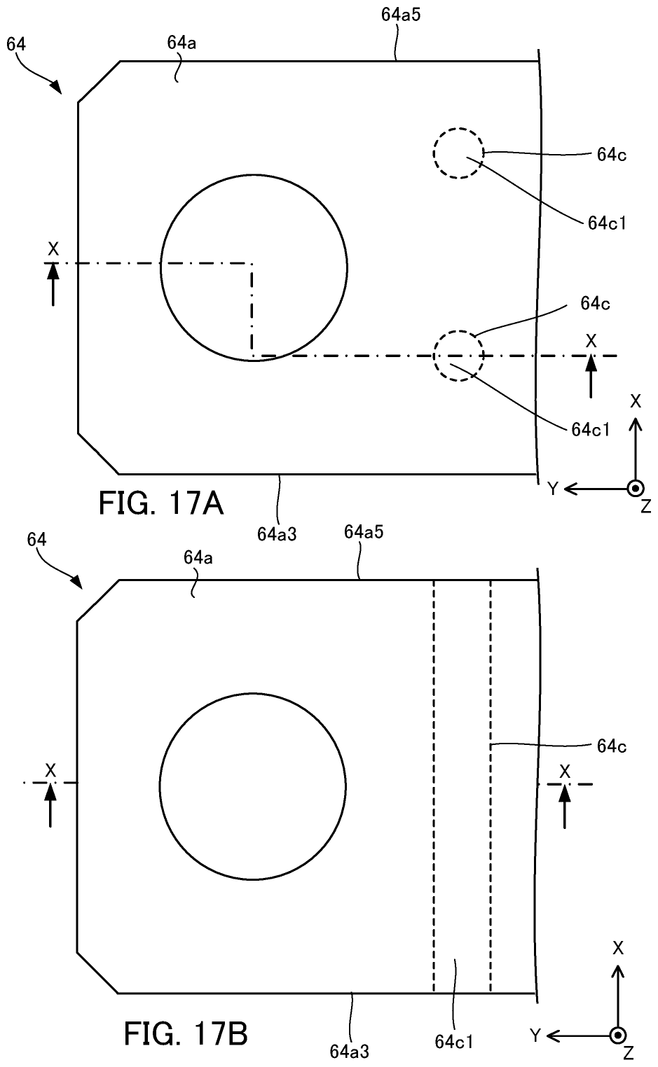

In modification 1-2, another form of the spacer 64c formed by press working in modification 1-1 will be described with reference to FIGS. 17A and 17B. FIGS. 17A and 17B illustrate the wiring member included in the power converter according to the first embodiment (modification 1-2). FIGS. 17A and 17B illustrate different modifications of the spacer. Furthermore, for sectional views taken along the dot-dash lines X-X of FIGS. 17A and 17B, FIG. 16B may be referred to.

With the external connection portion 64a illustrated in FIG. 17A, two spacers 64c are formed on the back surface 64a2 (not illustrated). The two spacers 64c are arranged in line with respect to the end side 64a4 and are parallel to the end side 64a4. Furthermore, two recesses 64c1 are formed in the front surface 64a1 of the external connection portion 64a opposite the spacers 64c. In order to form this external connection portion 64a, two press portions 71a are formed on the press working jig 71 included in the press apparatus 70 illustrated in FIG. 15. The external connection portion 64a of the wiring member 64 is pressed with the press working jig 71. By doing so, the wiring member 64 illustrated in FIG. 17A is obtained. The spacers 64c are semispheric. In addition, the spacers 64c are not always semispheric. For example, the spacers 64c may have the shape of a cube, a cone, a quadrangular pyramid, or a triangular pyramid. The shape of the spacers 64c depends on the shape of the press portions 71a of the press working jig 71. Moreover, the shape of the recesses 64c1 corresponding to the spacers 64c also depends on the shape of the press portions 71a of the press working jig 71. The number of spacers 64c is not limited to two. Three or more spacers 64c may be formed in line. In this case, three or more press portions 71a are also formed in line on the press working jig 71.

With the external connection portion 64a illustrated in FIG. 17B, a spacer 64c is formed on the back surface 64a2 (not illustrated) from the side 64a3 to the side 64a5. In order to form this external connection portion 64a, a press portion 71a having a shape corresponding to that of the spacer 64c is formed on the press working jig 71 included in the press apparatus 70 illustrated in FIG. The external connection portion 64a of the wiring member 64 is pressed with the press working jig 71. By doing so, the wiring member 64 illustrated in FIG. 17B is obtained. In addition, the spacer 64c is semicylindrical. However, for example, the spacer 64c may have the shape of a quadrangular prism or a triangular prism. If the spacer 64c has the shape of such a prism, then corner portions may be R-chamfered.

(Modification 1-3)

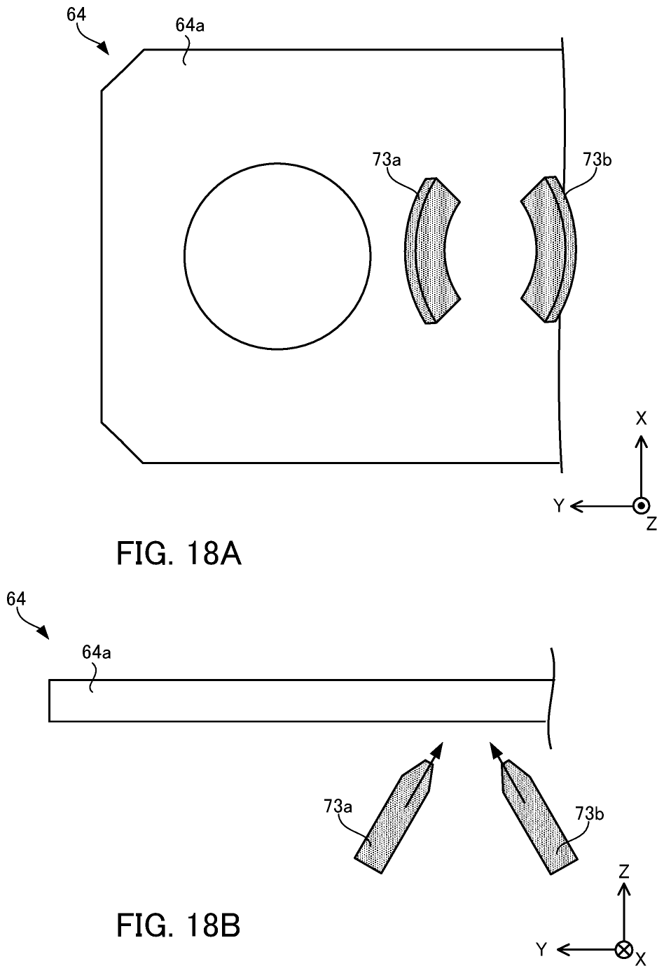

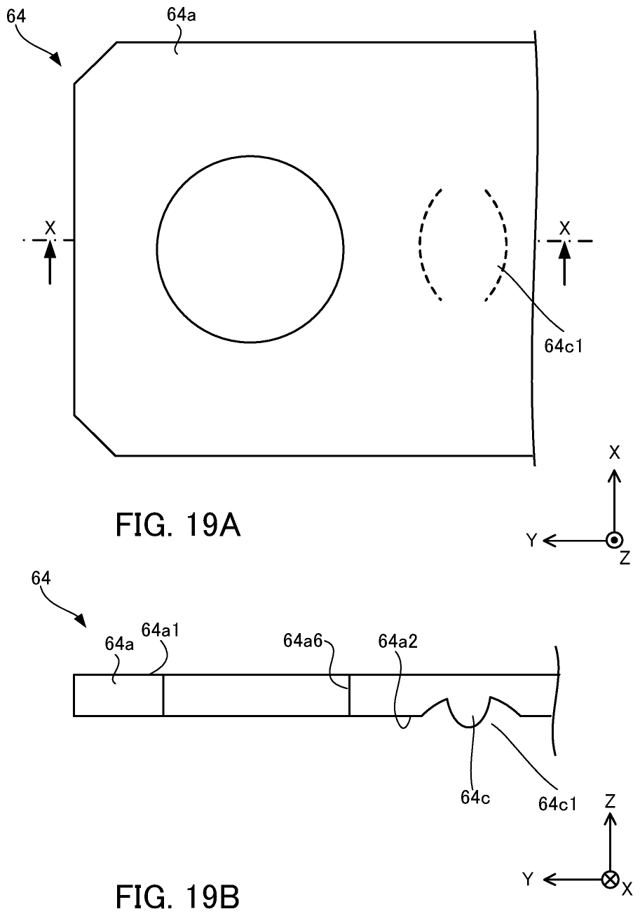

In modification 1-3, a case where the spacer 64c is formed on the wiring member 64 by pressing will be described with reference to FIGS. 18A and 18B and FIGS. 19A and 19B. FIGS. 18A and 18B illustrate pressing of the wiring member included in the method for manufacturing the power converter according to the first embodiment (modification 1-3). FIGS. 19A and 19B illustrate the wiring member included in the power converter according to the first embodiment (modification 1-3). FIG. 18A is a plan view of pressing of the external connection portion 64a of the wiring member 64 (viewed from the back surface). FIG. 18B is a side view of the pressing of the external connection portion 64a of the wiring member 64. FIG. 19A is a plan view of the pressed external connection portion 64a of the wiring member 64. FIG. 19B is a sectional view taken along the dot-dash line X-X of FIG. 19A.

A pair of pressing jigs 73a and 73b are pressed against an area of the external connection portion 64a of the wiring member 64 in which the spacer 64c is to be formed. The pair of pressing jigs 73a and 73b are semicylindrical. The hardness of a material for the pair of pressing jigs 73a and 73b is such that the wiring member 64 may be pressed with the pair of pressing jigs 73a and 73b. As illustrated in FIGS. 18A and 18B, one end portions of the pair of pressing jigs 73a and 73b are pressed against the external connection portion 64a. By doing so, as illustrated in FIGS. 19A and 19B, a recess 64c1 having a shape corresponding to that of the one end portions of the pair of pressing jigs 73a and 73b is formed in the area against which the one end portions of the pair of pressing jigs 73a and 73b are pressed. Furthermore, by forming the recess 64c1 in the external connection portion 64a, a portion surrounded by the recess 64c1 heaves and the spacer 64c is formed. That is to say, the recess 64c1 is formed in both side portions of the spacer 64c in the back surface 64a2 of the wiring member 64 along the spacer 64c with the pair of pressing jigs 73a and 73b.

The pair of pressing jigs 73a and 73b are not always semicylindrical. For example, the pair of pressing jigs 73a and 73b may have the shape of a flat plate. In this case, as illustrated in FIG. 17B, for example, a recess 64c1 is formed in the external connection portion 64a from the side 64a3 to the side 64a5 and a portion surrounded by the recess 64c1 heaves. As a result, the spacer 64c is formed.

(Modification 1-4)

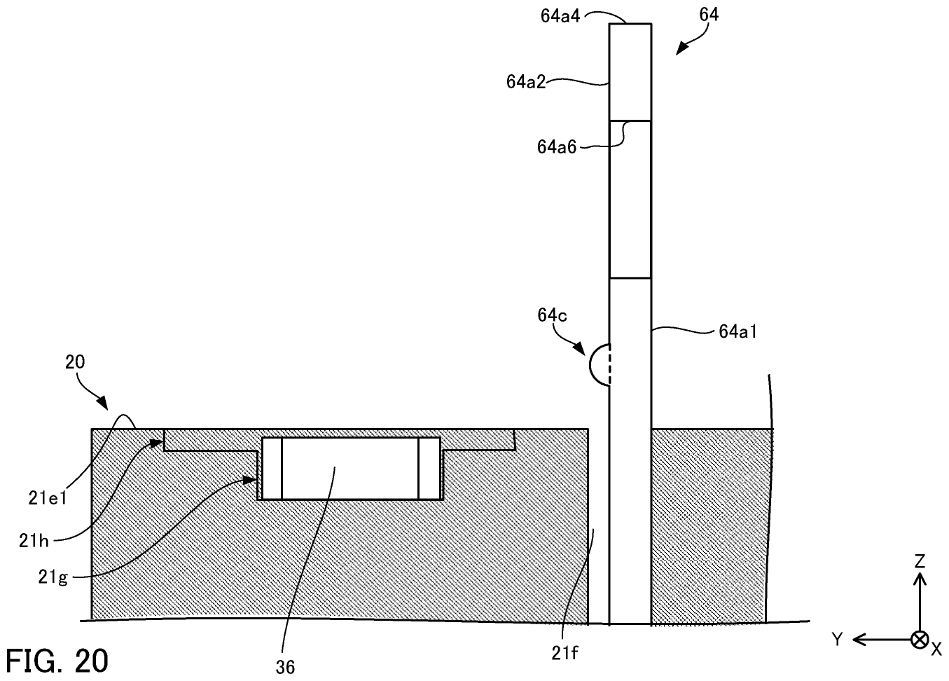

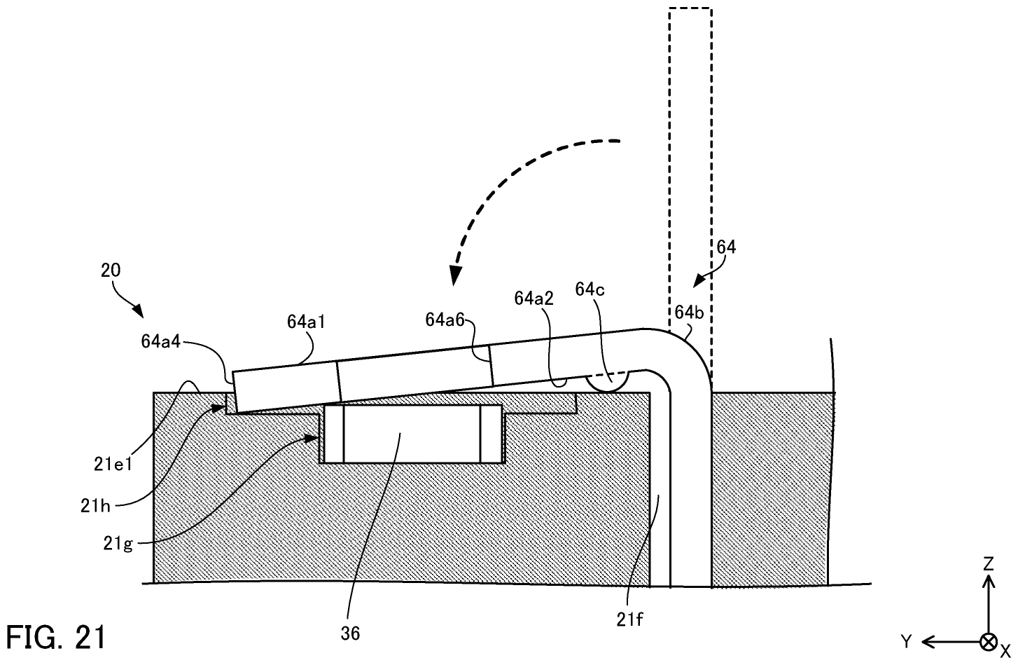

In modification 1-4, a case where a portion of the control terminal area 21e1 of the case 20 opposite the bent external connection portion 64a is recessed will be described with reference to FIG. 20 and FIG. 21. FIG. 20 illustrates a fixing process (after fixing) included in the method for manufacturing the power converter according to the first embodiment (modification 1-4). FIG. 21 illustrates a bending process included in the method for manufacturing the power converter according to the first embodiment (modification 1-4). FIG. 20 and FIG. 21 correspond to FIG. 10 and FIG. 11, respectively.

A hollow terminal receiving portion 21h is formed around the nut housing portion 21g in the control terminal area 21e1 of the case 20. The bottom surface of the terminal receiving portion 21h is situated below the control terminal area 21e1 and above the bottom surface of the nut housing portion 21g. Furthermore, the shape and size of the terminal receiving portion 21h are such that the bent external connection portion 64a fits into the terminal receiving portion 21h in plan view.

The power converter 10 including this case 20 is also manufactured in accordance with the method illustrated in FIG. 7. Steps S15 and S16 of FIG. 7 will now be described.

As illustrated in FIG. 20, when the case 20 is fixed in step S15 of FIG. 7, the wiring member 64 extends vertically upward (in the +Z direction) from the outlet 21f in the control terminal area 21e1 of the case 20.

Next, in step S16 of FIG. 7, the front surface 64a1 of the wiring member 64 extending vertically upward from the outlet 21f in the control terminal area 21e1 of the case 20 is pressed toward the control terminal area 21e1 of the case 20. By doing so, as illustrated in FIG. 21, the wiring member 64 bends with a portion near the outlet 21f as a fulcrum and the end side 64a4 of the external connection portion 64a comes in contact with the control terminal area 21e1. At this time, the external connection portion 64a enters the terminal receiving portion 21h formed in the control terminal area 21e1. That is to say, the external connection portion 64a is biased to the side of the case 20, compared with the FIG. 11 in the first embodiment. After that, pressure applied to the wiring member 64 is released. Accordingly, even if the external connection portion 64a of the wiring member 64 attempts to return to the original position, an inclination of the external connection portion 64a which is such that the end side 64a4 of the external connection portion 64a is situated above the bending portion 64b is prevented further.

As a result, a printed-circuit board is reliably fastened to the external connection portion 64a of the wiring member 64 with a screw and the printed-circuit board does not deform. This prevents deterioration in the reliability of the power converter 10.

### Second Embodiment

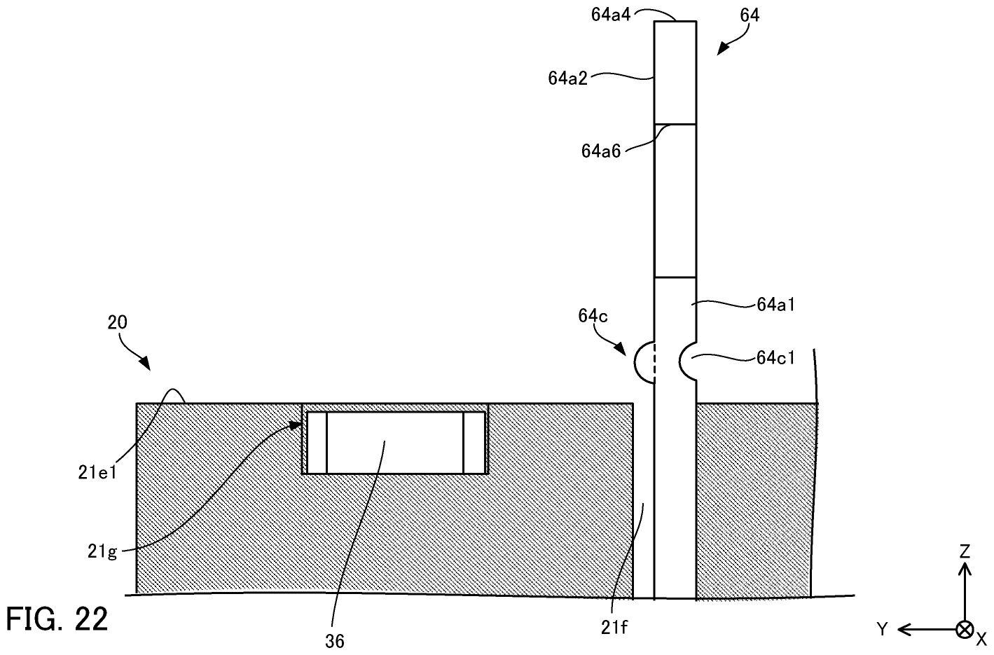

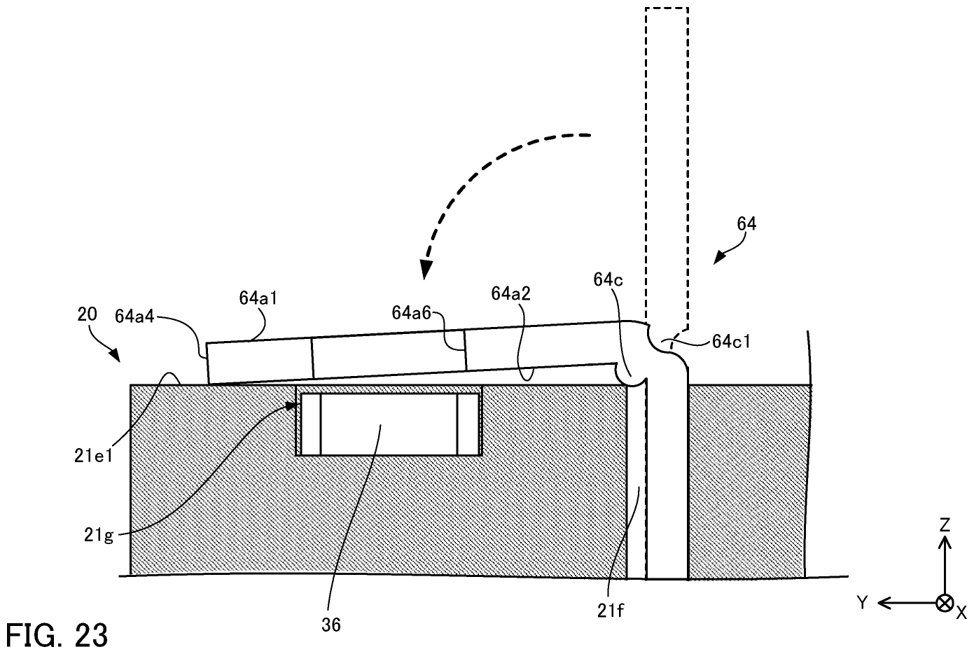

In a second embodiment, as in modification 1-1, a case where a wiring member 64 on which press working is performed is used will be described with reference to FIG. 22 and FIG. 23. FIG. 22 illustrates a fixing process (after fixing) included in a method for manufacturing a power converter according to a second embodiment. FIG. 23 illustrates a bending process included in the method for manufacturing the power converter according to the second embodiment.

A power converter 10 including the wiring member 64 on which a spacer 64c is formed by press working is also manufactured in accordance with the method illustrated in FIG. 7. Steps S15 and S16 of FIG. 7 will now be described.

As illustrated in FIG. 22, when a case 20 is fixed in step S15 of FIG. 7, the wiring member 64 extends vertically upward (in the +Z direction) from an outlet 21f in a control terminal area 21e1 of the case 20.

Next, in step S16 of FIG. 7, a front surface 64a1 of the wiring member 64 extending vertically upward from the outlet 21f in the control terminal area 21e1 of the case 20 is pressed toward the control terminal area 21e1 of the case 20. By doing so, as illustrated in FIG. 23, the wiring member 64 bends with a portion near the outlet 21f as a fulcrum and an end side 64a4 of an external connection portion 64a comes in contact with the control terminal area 21e1. Because the strength of the wiring member 64 at a recess 64c1 is lower than that of the rest of the wiring member 64, at this time the external connection portion 64a bends from the recess 64c1 in the front surface 64a1. After that, pressure applied to the wiring member 64 is released. Even if the external connection portion 64a of the wiring member 64 attempts to return to the original position, an inclination of the external connection portion 64a which is such that the end side 64a4 of the external connection portion 64a is situated above the bending portion 64b is prevented further. In particular, the thickness of the wiring member 64 at the recess 64c1 is smaller than that of the rest of the wiring member 64. Accordingly, the external connection portion 64a which bends from the recess 64c1 is less likely to return to the original position.

As a result, a printed-circuit board is reliably fastened to the external connection portion 64a of the wiring member 64 with a screw and the printed-circuit board does not deform. This prevents deterioration in the reliability of the power converter 10.

(Modification 2-1)

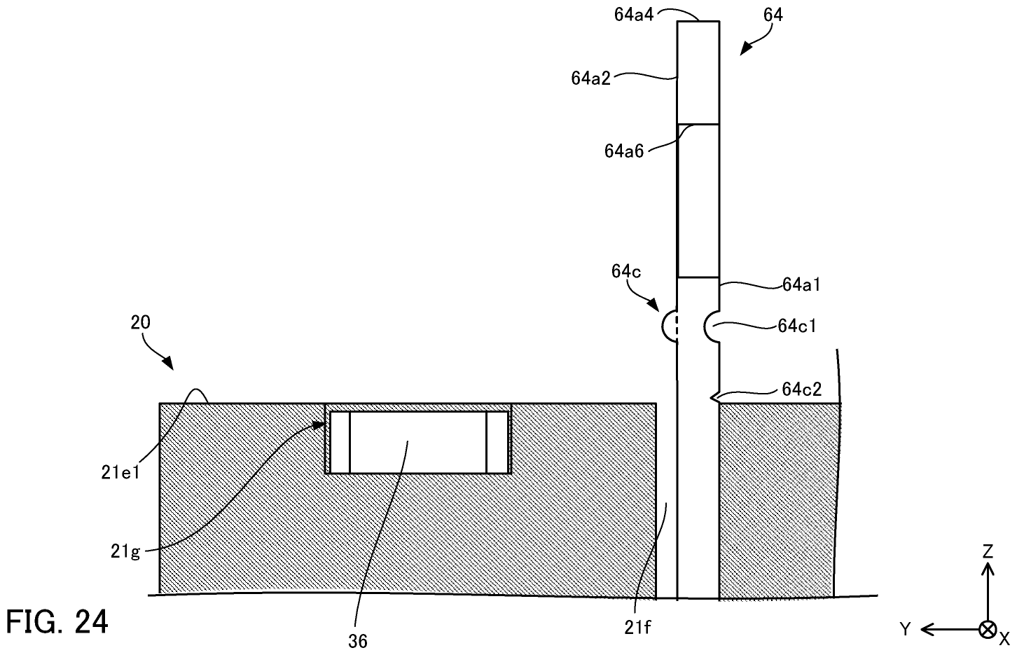

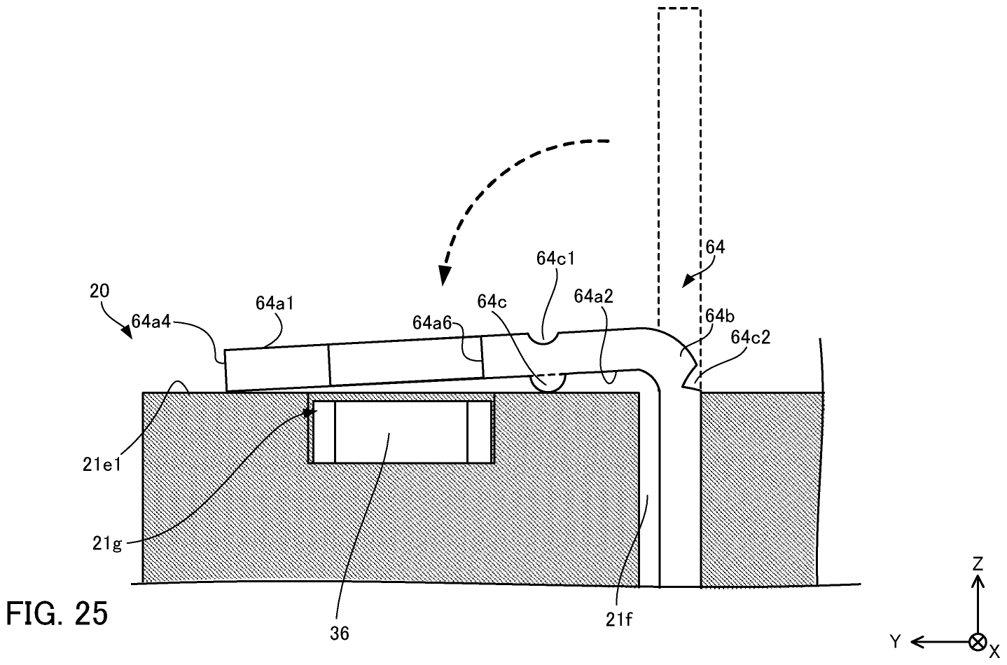

In the second embodiment, when the wiring member 64 is bent with the recess 64c1 as a fulcrum, the spacer 64c is located only opposite the recess 64c1. In modification 2-1, a case where when the wiring member 64 is bent with the recess 64c1 as a fulcrum, there is no limitation to the position of the spacer 64c will be described with reference to FIG. 24 and FIG. 25. FIG. 24 illustrates a fixing process (after fixing) included in a method for manufacturing the power converter according to the second embodiment (modification 2-1). FIG. 25 illustrates a bending process included in the method for manufacturing the power converter according to the second embodiment (modification 2-1). FIG. 24 and FIG. 25 correspond to FIG. 22 and FIG. 23, respectively.

In modification 2-1, the power converter 10 including the wiring member 64 on which the spacer 64c is formed by press working is also manufactured in accordance with the method illustrated in FIG. 7. With the wiring member 64 in modification 2-1, however, the spacer 64c (and the recess 64c1) are formed near a fastening hole 64a6.

Furthermore, a recess (second recess) 64c2 is formed in the front surface 64a1 of the wiring member 64 in modification 2-1. As described later, the recess 64c2 is formed in the front surface 64a1 of the wiring member 64 so that when the case 20 is fixed to the wiring member 64, the recess 64c2 will be situated near the outlet 21f. The recess 64c2 may be formed by slitting. In this case, the recess 64c2 may be formed so as to cross the wiring member 64 in the X direction. Furthermore, at this time, the depth of the recess 64c2 is such that when the wiring member 64 is bent, the wiring member 64 is not cut. In addition, the recess 64c2 may be formed by press working. In this case, a plurality of recesses 64c2 may be formed along the width in the X direction of the wiring member 64. A case where the recess 64c2 is formed by slitting is taken as an example. In modification 2-1, steps S15 and S16 of FIG. 7 are also described.

As illustrated in FIG. 24, when the case 20 is fixed in step S15 of FIG. 7, the wiring member 64 extends vertically upward (in the +Z direction) from the outlet 21f in the control terminal area 21e1 of the case 20. At this time, the recess 64c2 of the wiring member 64 is situated in the outlet 21f of the case 20.

Next, in step S16 of FIG. 7, the front surface 64a1 of the wiring member 64 extending vertically upward from the outlet 21f in the control terminal area 21e1 of the case 20 is pressed toward the control terminal area 21e1 of the case 20. By doing so, as illustrated in FIG. 25, the wiring member 64 bends with a portion near the outlet 21f as a fulcrum and an end side 64a4 of an external connection portion 64a comes in contact with the control terminal area 21e1. Because the strength of the wiring member 64 at the recess 64c2 is lower than that of the rest of the wiring member 64, at this time the external connection portion 64a bends from the recess 64c2 in the front surface 64a1. After that, pressure applied to the wiring member 64 is released. Even if the external connection portion 64a of the wiring member 64 attempts to return to the original position, an inclination of the external connection portion 64a which is such that the end side 64a4 of the external connection portion 64a is situated above the bending portion 64b is prevented further. In particular, the thickness of the wiring member 64 at the recess 64c2 from which the external connection portion 64a bends is smaller than that of the rest of the wiring member 64. Accordingly, the external connection portion 64a which bends from the recess 64c2 is less likely to return to the original position.

As a result, a printed-circuit board is reliably fastened to the external connection portion 64a of the wiring member 64 in modification 2-1 with a screw and the printed-circuit board does not deform. This prevents deterioration in the reliability of the power converter 10.

### Third Embodiment

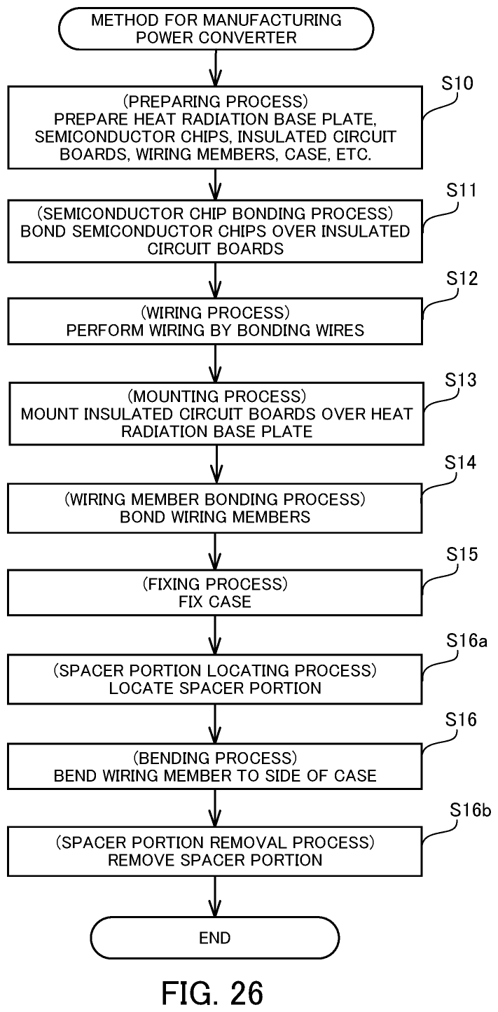

With a power converter according to a third embodiment, an external connection portion 64a of a wiring member 64 does not include a spacer 64c and is approximately parallel to a control terminal area 21e1 of a case 20. A method for manufacturing such a power converter will be described with reference to FIG. 26. FIG. 26 is a flow chart illustrative of a method for manufacturing the power converter according to the third embodiment.

First, a preparing process for preparing components of the power converter is performed (step S10). Components prepared in the preparing process are a heat radiation base plate 35, first semiconductor chips 40a and second semiconductor chips 41a and 41b, insulated circuit boards 31, various wiring members 61 through 64, a case 20, and the like. The wiring member 64 prepared in the preparing process does not include a spacer 64c and a front surface 64a1 and a back surface 64a2 of the wiring member 64 are approximately flat. Components not described here are also prepared.

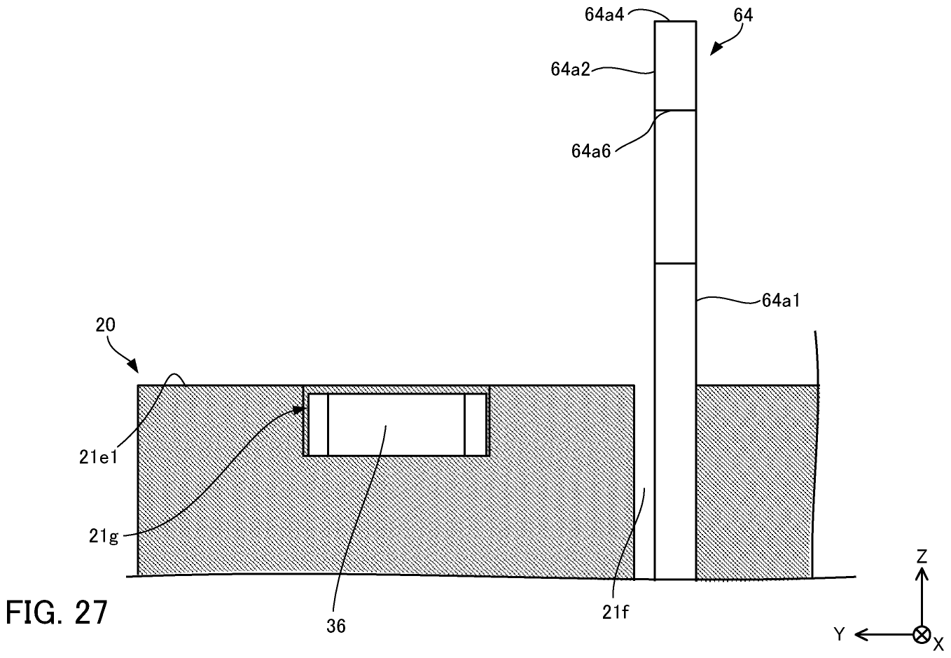

Next, steps S11 through S14 are performed. Steps S11 through S14 performed for manufacturing the power converter according to the third embodiment are the same as steps S11 through S14, respectively, of FIG. 7. Next, a fixing process for fixing the case 20 to the heat radiation base plate 35 over which semiconductor units 30 to which the wiring members 61, 62, and 63 are bonded and control wiring units 50 are mounted is performed (step S15). The fixing process will be described with reference to FIG. 27. FIG. 27 illustrates the fixing process (after fixing) included in the method for manufacturing the power converter according to the third embodiment. FIG. 27 corresponds to FIG. 10 in the first embodiment and is a sectional view of the wiring member 64 drawn out from the control terminal area 21e1 after fixing the case 20.

The case 20 is fixed from above to the heat radiation base plate 35 over which the semiconductor units 30 to which the wiring members 61, 62, and 63 are bonded and the control wiring units 50 are mounted (see FIG. 9). At this time, an adhesive is applied in advance to bottom portions of a long side wall 21a, a short side wall 21b, a long side wall 21c, and a short side wall 21d of the case 20 and the case 20 is bonded to an outer peripheral portion of the heat radiation base plate 35.

As illustrated in FIG. 27, for example, when the case 20 is fixed in this way, the wiring member 64 extends vertically upward (in the +Z direction) from an outlet 21f in the control terminal area 21e1 of the case 20. For control terminal area 21e2 through 21e6 (not illustrated), the wiring member 64 extends vertically upward from the outlet 21f. This is the same with FIG. 27.

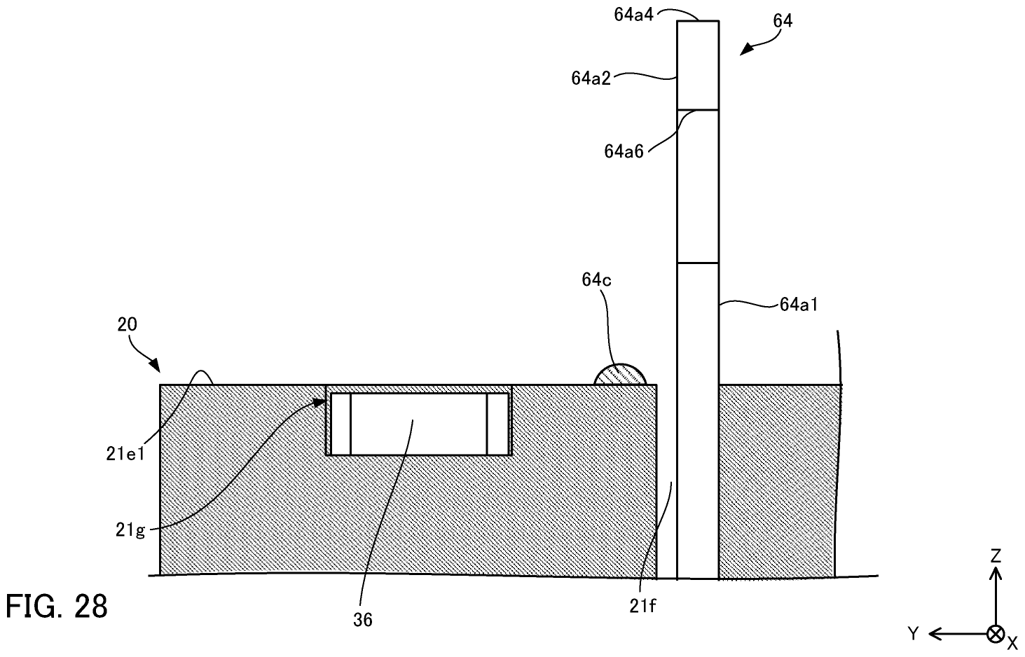

Next, a spacer locating process for locating a spacer 64c on the control terminal area 21e1 of the case 20 is performed (step S16a). The spacer locating process will be described with reference to FIG. 28. FIG. 28 illustrates a spacer locating process included in the method for manufacturing the power converter according to the third embodiment. The spacer 64c is located near the outlet 21f on the control terminal area 21e1 of the case 20. The spacer 64c may have the shape of a pole. As described in FIG. 10, for example, the spacer 64c may be semicylindrical. Alternatively, the spacer 64c may have the shape of a quadrangular prism or a triangular prism. Furthermore, a position in which the spacer 64c is located may correspond to the position of the spacer 64c at the time of the external connection portion 64a in the first embodiment being bent. The hardness of a material for the spacer 64c is such that the spacer 64c may withstand pressure from the wiring member 64.

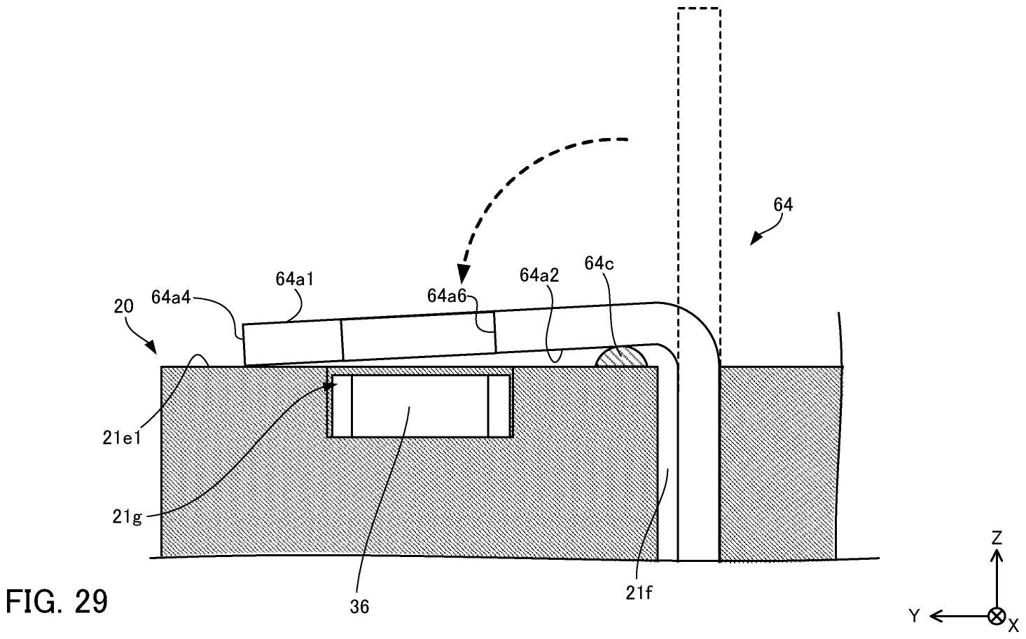

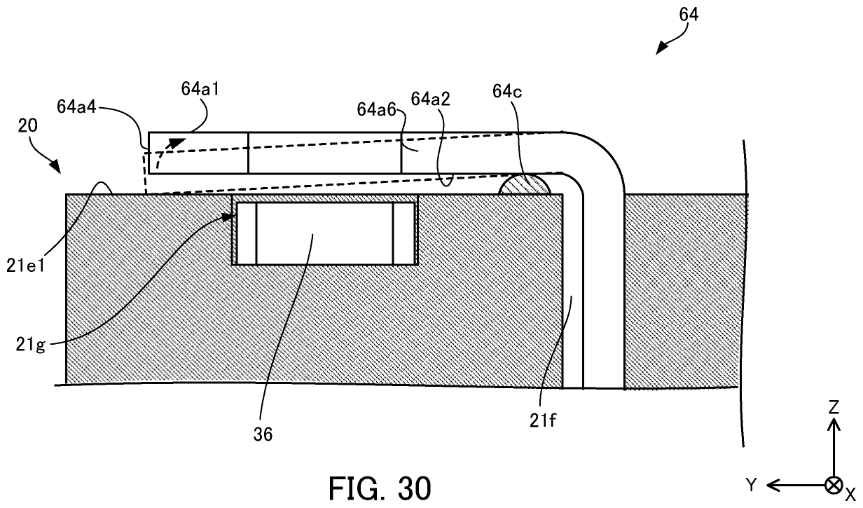

Next, a bending process for bending the wiring member 64 to the side of the case 20 is performed (step S16). The bending process will be described with reference to FIG. 29 and FIG. 30. FIGS. 29 and 30 illustrate the bending process included in the method for manufacturing the power converter according to the third embodiment.

As illustrated in FIG. 28, the front surface 64a1 of the wiring member 64 extending vertically upward from the outlet 21f in the control terminal area 21e1 of the case 20 is pressed toward the control terminal area 21e1 of the case 20. By doing so, the wiring member 64 bends with a portion near the outlet 21f as a fulcrum and the external connection portion 64a falls toward the control terminal area 21e1. When the front surface 64a1 of the wiring member 64 is continuously pressed in the same direction, the external connection portion 64a comes in contact with the spacer 64c located on the control terminal area 21e1. As illustrated in FIG. 29, when the front surface 64a1 of the wiring member 64 is pressed further, an end side 64a4 of the external connection portion 64a comes in contact with the control terminal area 21e1 with the spacer 64c as a fulcrum.

After that, pressure applied to the wiring member 64 is released. The external connection portion 64a of the wiring member 64 pressure on which is released attempts to return to the original position to restore a state in which the wiring member 64 is not yet bent. Just after the pressure applied to the wiring member 64 is released, the external connection portion 64a is inclined to a degree that the end side 64a4 of the external connection portion 64a comes in contact with the control terminal area 21e1 with the spacer 64c as a fulcrum. Accordingly, it is assumed that the external connection portion 64a attempts to return to the original position. As illustrated in FIG. for example, the external connection portion 64a returns to, at the most, a height at which the external connection portion 64a is approximately parallel to the control terminal area 21e1. That is to say, the external connection portion 64a may be inclined so that the end portion (end side 64a4) of the external connection portion 64a will be apart from the control terminal area 21e1 and so that the end portion (end side 64a4) of the external connection portion 64a will be situated below a bending portion 64b. The above described bending process is performed on each wiring member 64.

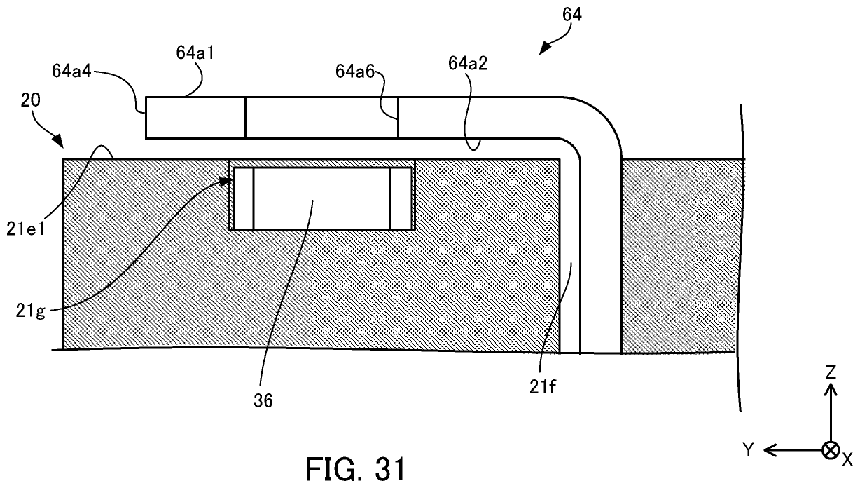

Next, a spacer removal process for removing the spacer 64c is performed (step S16b). The spacer removal process will be described with reference to FIG. 31. FIG. 31 illustrates the spacer removal process included in the method for manufacturing the power converter according to the third embodiment. After step S16 is performed, the spacer 64c is removed from the control terminal area 21e1 of the case 20. As a result, as illustrated in FIG. 31, the spacer 64c is removed from between the external connection portion 64a and the control terminal area 21e1 of the case 20 and the external connection portion 64a is kept approximately parallel to the control terminal area 21e1 of the case 20. By performing the above processes, the power converter is manufactured.

Even with this power converter, the external connection portion 64a of the wiring member 64 returns to a height at which the external connection portion 64a is approximately parallel to the control terminal area 21e1. Even if a printed-circuit board is located on the external connection portion 64a of the wiring member 64 and is fastened to the external connection portion 64a with a screw, the external connection portion 64a does not strike against the printed-circuit board. As a result, the printed-circuit board does not deform and is properly fastened to the wiring member 64. This suppresses deterioration in the reliability of the power converter.

The terminal receiving portion 21h in modification 1-4 may be formed in the control terminal area 21e1 of the case 20 in the third embodiment.

According to the disclosed techniques, the inclination of a wiring member drawn out from a case is decreased, a printed-circuit board is properly fastened to the wiring member, and deterioration in the reliability of a power converter is suppressed.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A power converter, comprising:
a case having principal surface, and including an outlet with an outlet opening at the principal surface; and
a wiring member having, as a drawn-out portion, a portion that extends out from the outlet opening, and is bent at the outlet opening toward the principal surface, wherein
the drawn-out portion of the wiring member has a first surface facing the principal surface and includes a spacer provided on the first surface at a position adjacent to the outlet opening, the spacer being sandwiched between the first surface of the drawn-out portion and the principal surface of the case.

2. The power converter according to claim 1, wherein:
the spacer protrudes from the first surface of the drawn-out portion of the wiring member; and
the drawn-out portion has a second surface opposite to the first surface, the second surface having a recess provided at a position overlapping a position of the spacer on the first surface in a view from a direction orthogonal to the first and second surfaces.

3. The power converter according to claim 1, wherein the first surface of the drawn-out portion has two recesses respectively provided along opposing sides of the spacer.

4. The power converter according to claim 1, wherein:
the drawn-out portion of the wiring member has a fastening hole; and
the spacer is located in an area between adjacent to the outlet opening of the case and the fastening hole of the drawn-out portion.

5. The power converter according to claim 4, wherein the spacer includes one or more spacers arranged between two opposing sides of the drawn-out portion that are parallel to a direction in which the drawn-out portion extends from the outlet opening.

6. The power converter according to claim 4, wherein the spacer extends between two sides of the drawn-out portion that are parallel to a direction in which the drawn-out portion extends from the outlet.

7. The power converter according to claim 1, wherein the case has a hollow terminal receiving portion provided at the principal surface at a position facing the drawn-out portion of the wiring member.

8. The power converter according to claim 1, wherein the first surface of the drawn-out portion of the wiring member is approximately parallel to the principal surface of the case, or the first surface of the drawn-out portion of the wiring member inclines toward the principal surface such that the first surface at one side of the drawn-out portion is closer to the principal surface of the case than is the first surface at an other side of the drawn-out portion, the one side of the drawn-out portion being farther from the outlet opening than is the other side of the drawn-out portion.

9. A power converter manufacturing method, comprising:
preparing a case having a first principal surface and a second principal surface opposite to each other and having an outlet with an outlet opening at the first principal surface, the outlet extending in the case from the second principal surface to the first principal surface;
preparing a wiring member extending in one direction; and
inserting the wiring member through the outlet in a direction from the second principal surface to the first principal surface, and drawing the wiring member out of the case from the outlet opening at the first principal surface to form a drawn-out portion outside of the case, and bending the drawn-out portion, at a position thereof that is adjacent to the outlet opening, toward the first principal surface, with the first surface facing the first principal surface, while sandwiching a spacer between the first surface of a drawn-out portion and the first principal surface.

10. The power converter manufacturing method according to claim 9, wherein the spacer is formed on the first surface of the drawn-out portion of the wiring member at a position adjacent to the outlet opening.

11. The power converter manufacturing method according to claim 10, wherein the preparing the case and the wiring member includes:
forming the spacer on the first surface of the wiring member by performing a press working on a second surface of the wiring member opposite to the first surface of the wiring member, thereby to form a first recess on the second surface at a position overlapping a position of the spacer on the first surface in a view from a direction orthogonal to the first and second surfaces.

12. The power converter manufacturing method according to claim 9, further comprising forming a second recess on a second surface of the wiring member opposite to the first surface of the wiring member as a bending point,
wherein the bending the wiring member includes bending the wiring member at the second recess.

13. The power converter manufacturing method according to claim 9, further comprising preparing the spacer, wherein:
the bending the wiring member includes, after the wiring member is drawn out from the outlet, placing the spacer at a position adjacent to the outlet opening of the case, and bending the drawn-out portion so as to face the first principal surface; and
removing the spacer from the drawn-out portion after the wiring member is bent.
